(19) United States
(12) Patent Application Publication
(10) Pub. No.: US 2024/0021631 A1
(43) Pub. Date: Jan. 18, 2024

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventor: Hiroaki AMMO, Kanagawa (JP)

(73) Assignee: SONY SEMICONDUCTOR SOLUTIONS CORPORATION, Kanagawa (JP)

(21) Appl. No.: 18/255,429

(22) PCT Filed: Oct. 25, 2021
(86) PCT No.: PCT/JP2021/039195

§ 371 Date: Jun. 1, 2023

(30) Foreign Application Priority Data
Dec. 10, 2020 (JP) 2020-204933

(51) Int. Cl. H01L 27/146

(52) U.S. Cl. CPC H01L 27/14614; H01L 27/14645

(57) ABSTRACT

The purpose of the present technology is to improve photoelectric conversion efficiency. A first semiconductor layer, a second semiconductor layer on a side of the first semiconductor layer remote from a light incident surface, a photoelectric conversion part in the first semiconductor layer, a charge holding region in the first semiconductor layer and configured to accumulate a signal charge generated by photoelectric conversion performed by the photoelectric conversion part, first and second field effect transistors each including a gate electrode and a pair of main electrode regions, each of the pairs of main electrode regions being provided in the second semiconductor layer, and a contact electrode extending through the first and second semiconductor layers and directly connected to any one of the pair of main electrode regions of the first field effect transistor, the gate electrode of the second field effect transistor, and the charge holding region are included.

### TECHNICAL FIELD

The present technology (technology according to the present disclosure) relates to a solid-state imaging device and an electronic device, and particularly relates to a technology effective when applied to a solid-state imaging device including a plurality of semiconductor layers stacked on top of each other and an electronic device including the solid-state imaging device.

### BACKGROUND ART

As a solid-state imaging device, for example, Patent Document 1 discloses a solid-state imaging device having a three-dimensional structure in which a plurality of semiconductor layers each provided with an element such as a transistor is stacked on top of each other to increase element density in a stacking direction. With such a three-dimensional structure, it is possible to increase the number of elements every time a layer such as a second layer or a third layer is stacked rather than using only one layer, and even when pixels are miniaturized, it is possible to provide an arrangement area adequate for a photoelectric conversion part and a pixel transistor.

### CITATION LIST

### Patent Document

Patent Document 1: WO 2017/138197

### SUMMARY OF THE INVENTION

### Problems to be Solved by the Invention

Meanwhile, in the solid-state imaging device having a three-dimensional structure, a charge holding region (floating diffusion) provided in a first semiconductor layer and a pixel transistor provided in a second semiconductor layer are electrically connected by a conductive path including a contact electrode that extends in a vertical direction (thickness direction of the semiconductor layer) through the first and second semiconductor layers and a wiring that is provided in a wiring layer on the second semiconductor layer and extends in a horizontal direction (two-dimensional plane direction). With such a conductive path, wiring capacitance (parasitic capacitance) is added to the contact electrode and the wiring. The wiring capacitance causes a decrease in photoelectric conversion rate, so that there is room for improvement.

It is therefore an object of the present technology to improve photoelectric conversion efficiency.

### Solutions To Problems

A solid-state imaging device according to an aspect of the present technology includes:
a first semiconductor layer;
a second semiconductor layer provided on a side of the first semiconductor layer remote from a light incident surface;
a photoelectric conversion part provided in the first semiconductor layer;
a charge holding region provided in the first semiconductor layer and configured to accumulate a signal charge generated by photoelectric conversion performed by the photoelectric conversion part;
first and second field effect transistors each including a gate electrode and a pair of main electrode regions, each of the pairs of main electrode regions being provided in the second semiconductor layer; and
a contact electrode extending through the first and second semiconductor layers and directly connected to any one of the pair of main electrode regions of the first field effect transistor, the gate electrode of the second field effect transistor, and the charge holding region.

Furthermore, an electronic device according to another aspect of the present technology includes the solid-state imaging device, and an optical system configured to form an image of image light from a subject on the solid-state imaging device.

### BRIEF DESCRIPTION OF DRAWINGS

FIG. 1 is a planar layout diagram schematically illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram of a pixel unit of the solid-state imaging device according to the first embodiment of the present technology.

FIG. 4 is a plan view of a main part, schematically illustrating a configuration example of the pixel unit of the solid-state imaging device according to the first embodiment of the present technology.

FIG. 5 is a cross-sectional view schematically illustrating a cross-sectional structure taken along a line A4-A4 in FIG. 4.

FIG. 5B is a cross-sectional view schematically illustrating a cross-sectional structure taken along a line B4-B4 in FIG. 4.

FIG. 6A is a plan view of a semiconductor wafer.

FIG. 6B is an enlarged view of a region B in FIG. 6A, illustrating a configuration of a chip formation region.

FIG. 7A is a process cross-sectional view schematically illustrating a process of a method for manufacturing the solid-state imaging device according to the first embodiment of the present technology.

FIG. 7B is a process cross-sectional view schematically illustrating a process of the method for manufacturing the solid-state imaging device according to the first embodiment of the present technology.

FIG. 8A is a process cross-sectional view subsequent to FIG. 7A.

FIG. 8B is a process cross-sectional view subsequent to FIG. 7B.

FIG. 9A is a process cross-sectional view subsequent to FIG. 8A.

FIG. 9B is a process cross-sectional view subsequent to FIG. 8B.

FIG. 10A is a process cross-sectional view subsequent to FIG. 9A.

FIG. 10B is a process cross-sectional view subsequent to FIG. 9B.

FIG. 11A is a process cross-sectional view subsequent to FIG. 10A.

FIG. 11B is a process cross-sectional view subsequent to FIG. 10B.

FIG. 12A is a process cross-sectional view subsequent to FIG. 11A.

FIG. 12B is a process cross-sectional view subsequent to FIG. 11B.

FIG. 13A is a process cross-sectional view subsequent to FIG. 12A.

FIG. 13B is a process cross-sectional view subsequent to FIG. 12B.

FIG. 14A is a process cross-sectional view subsequent to FIG. 13A.

FIG. 14B is a process cross-sectional view subsequent to FIG. 13B.

FIG. 15A is a process cross-sectional view subsequent to FIG. 14A.

FIG. 15B is a process cross-sectional view subsequent to FIG. 14B.

FIG. 16A is a process cross-sectional view subsequent to FIG. 15A.

FIG. 16B is a process cross-sectional view subsequent to FIG. 15B.

FIG. 17 is a plan view of a main part, schematically illustrating a configuration example of a pixel unit of a solid-state imaging device according to a second embodiment of the present technology.

FIG. 18 is a cross-sectional view schematically illustrating a cross-sectional structure taken along a line A17-A17 in FIG. 17.

FIG. 19 is an equivalent circuit diagram illustrating a configuration example of a pixel unit of a solid-state imaging device according to a third embodiment of the present technology.

FIG. 20 is a plan view of a main part, schematically illustrating a configuration example of the pixel unit of the solid-state imaging device according to the third embodiment of the present technology.

FIG. 21A is a cross-sectional view schematically illustrating a cross-sectional structure taken along a line A20-A20 in FIG. 20.

FIG. 21B is a cross-sectional view schematically illustrating a cross-sectional structure taken along a line B20-B20 in FIG. 20.

FIG. 22 is an equivalent circuit diagram illustrating a configuration example of a pixel unit of a solid-state imaging device according to a fourth embodiment of the present technology.

FIG. 23 is a plan view of a main part, schematically illustrating a configuration example of the pixel unit of the solid-state imaging device according to the fourth embodiment of the present technology.

FIG. 24 is an equivalent circuit diagram illustrating a configuration example of a pixel unit of a solid-state imaging device according to a fifth embodiment of the present technology.

FIG. 25 is a plan view of a main part, schematically illustrating a configuration example of the pixel unit of the solid-state imaging device according to the fifth embodiment of the present technology.

FIG. 26 is a diagram illustrating a schematic configuration of an electronic device according to a sixth embodiment of the present technology.

### MODE FOR CARRYING OUT THE INVENTION

Hereinafter, embodiments of the present technology will be described in detail with reference to the drawings.

In the description of the drawings referred to in the following description, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it goes without saying that dimensional relationships and ratios are partly different among the drawings. Furthermore, the effects described herein are merely examples and are not limited, and other effects may be provided.

Furthermore, the following embodiments illustrate a device and a method for embodying the technical idea of the present technology, and do not specify the configuration as follows. That is, various modifications can be made to the technical idea of the present technology within the technical scope described in the claims.

Furthermore, the definitions of directions such as up and down in the following description are merely defined for convenience of description, and do not limit the technical idea of the present technology. For example, it is a matter of course that when an object is observed by rotating the object by 90°, the up and down are converted into and read as left and right, and when the object is observed by rotating the object by 180°, the up and down are inverted and read.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor substrate 21 to be described below will be described as the Z direction.

### First Embodiment

In the first embodiment, an example in which the present technology is applied to a solid-state imaging device that is a back-illuminated complementary metal oxide semiconductor (CMOS) image sensor will be described.

### <<Overall Configuration of Solid-State Imaging Device>>

First, an overall configuration of a solid-state imaging device 1A will be described.

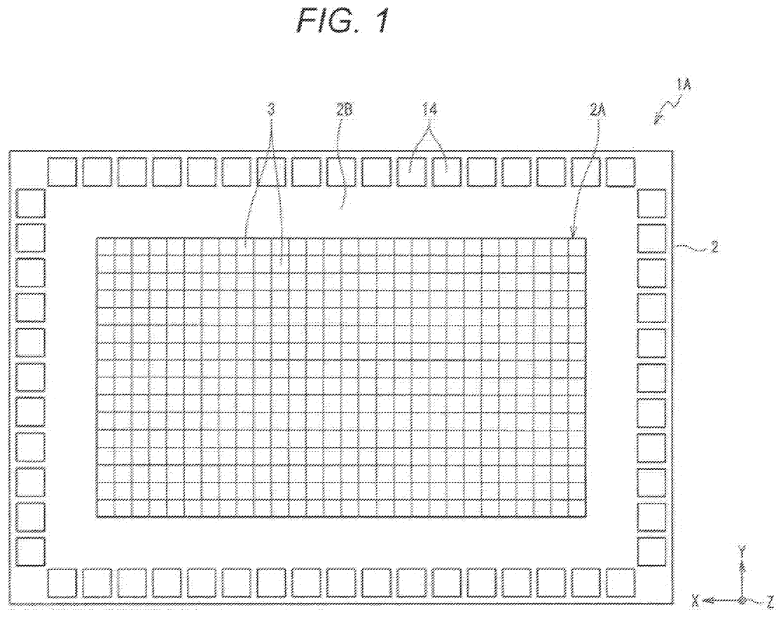

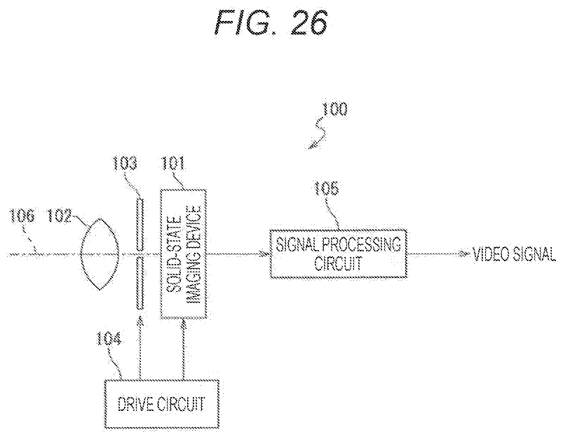

As illustrated in FIG. 1, the solid-state imaging device 1A according to the first embodiment of the present technology mainly includes a semiconductor chip 2 having a rectangular two-dimensional planar shape in plan view. In other words, the solid-state imaging device 1A is mounted on the semiconductor chip 2. As illustrated in FIG. 26, the solid-state imaging device 1A receives image light (incident light 106) from a subject through an optical lens 102, converts an amount of the incident light 106 formed as an image on an imaging surface into an electrical signal for each pixel, and outputs the electrical signal as a pixel signal.

As illustrated in FIG. 1, the semiconductor chip 2 on which the solid-state imaging device 1A is mounted includes, in a two-dimensional plane including the X direction and the Y direction orthogonal to each other, a rectangular pixel region 2A provided in a central portion, and a peripheral region 2B arranged outside the pixel region 2A so as to surround the pixel region 2A.

The pixel region 2A is, for example, a light receiving surface that receives light condensed by the optical lens (optical system) 102 illustrated in FIG. 26. Then, in the pixel region 2A, a plurality of pixels 3 is arranged in a matrix in the two-dimensional plane including the X direction and the Y direction. In other words, the pixels 3 are repeatedly arranged in the X direction and the Y direction orthogonal to each other in the two-dimensional plane.

As illustrated in FIG. 1, a plurality of bonding pads 14 is arranged in the peripheral region 2B. The plurality of bonding pads 14 is arranged, for example, along four sides in the two-dimensional plane of the semiconductor chip 2. Each of the plurality of bonding pads 14 is an input-output terminal used when the semiconductor chip 2 is electrically connected to an external device.

### <Logic Circuit>

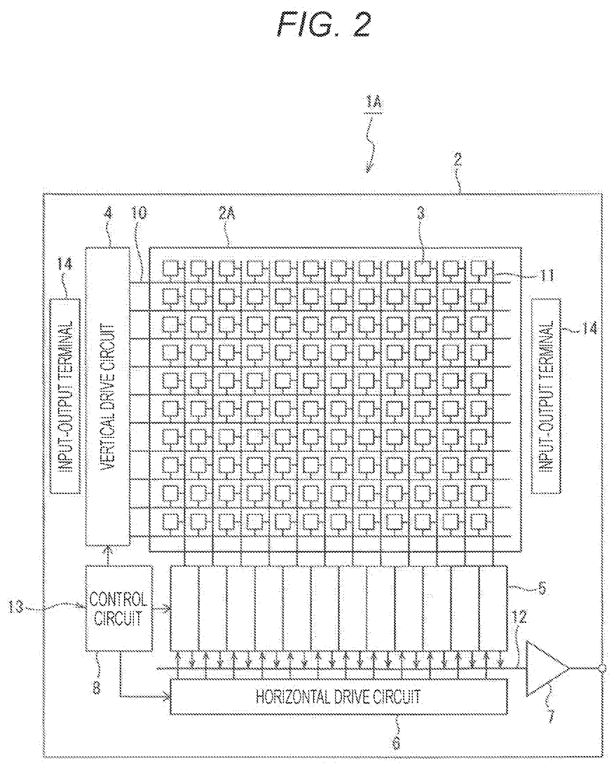

As illustrated in FIG. 2, the semiconductor chip 2 includes a logic circuit 13 including a vertical drive circuit 4, a column signal processing circuit 5, a horizontal drive circuit 6, an output circuit 7, a control circuit 8, and the like. The logic circuit 13 outputs an output voltage (Vout) for each pixel 3 to the outside. The logic circuit 13 includes, for example, a complementary MOS (CMOS) circuit including a metal oxide semiconductor field effect transistor (MOSFET) of a p-channel conductivity type (first conductivity type) and a MOSFET of an n-channel conductivity type (second conductivity type) as field effect transistors.

The vertical drive circuit 4 includes, for example, a shift register. The vertical drive circuit 4 sequentially selects a desired pixel drive line 10, supplies a pulse for driving the pixel 3 to the selected pixel drive line 10, and drives each pixel 3 row by row. That is, the vertical drive circuit 4 selectively scans each pixel 3 in the pixel region 2A sequentially in a vertical direction on a row-by-row basis, and a pixel signal from the pixel 3 based on a signal charge generated according to the amount of received light by a photoelectric conversion element of each pixel 3 is supplied to the column signal processing circuit 5 through a vertical signal line 11.

The column signal processing circuit 5 is arranged, for example, on every column of the pixels 3 and performs signal processing, such as noise removal on signals output from the pixels 3 of one row, for every pixel column. For example, the column signal processing circuit 5 performs signal processing such as correlated double sampling (CDS) for removing pixel-specific fixed pattern noise and analog digital (AD) conversion.

The horizontal drive circuit 6 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output the pixel signal subjected to the signal processing to a horizontal signal line 12.

The output circuit 7 performs signal processing on pixel signals sequentially supplied from each of the column signal processing circuits 5 through the horizontal signal line 12 and outputs processed signals. As the signal processing, for example, buffering, black level adjustment, column variation correction, various digital signal processing, and the like can be used.

The control circuit 8 generates, on the basis of a vertical synchronization signal, a horizontal synchronization signal, and a master clock signal, a clock signal or a control signal in accordance with which the vertical drive circuit 4, the column signal processing circuit 5, the horizontal drive circuit 6, and the like operate. Then, the control circuit 8 outputs the clock signal or control signal thus generated to the vertical drive circuit 4, the column signal processing circuit 5, the horizontal drive circuit 6, and the like.

### <Pixel Unit>

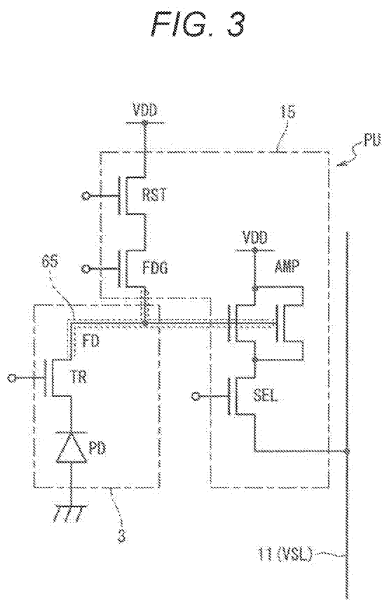

The semiconductor chip 2 includes, but is not limited to, a pixel unit PU illustrated in FIG. 3, for example. As illustrated in FIG. 3, the pixel unit PU includes one pixel 3 and a readout circuit 15 that reads out a signal charge held in the one pixel 3.

The pixel 3 includes a photoelectric conversion element PD, a transfer transistor TR, and a charge holding region (floating diffusion) FD. The photoelectric conversion element PD generates a signal charge corresponding to the amount of received light. The transfer transistor TR transfers the signal charge generated by photoelectric conversion performed by the photoelectric conversion element PD to the charge holding region FD. The charge holding region FD temporarily holds (accumulates) the signal charge transferred from the photoelectric conversion element PD via the transfer transistor TR. The transfer transistor TR includes, as a field effect transistor, a MOSFET in which a gate insulating film includes a silicon oxide (SiO₂), for example. The transfer transistor TR may be a metal insulator semiconductor FET (MISFET) in which a gate insulating film includes a silicon nitride (Si₃N₄) film or a multilayer film including, for example, a silicon nitride film and a silicon oxide film.

The photoelectric conversion element PD has a cathode side electrically connected to a source region of the transfer transistor TR, and an anode side electrically connected to a reference potential line (for example, a ground potential line). As the photoelectric conversion element PD, for example, a photodiode is used. A drain region of the transfer transistor TR is also used as the charge holding region FD, and a gate electrode of the transfer transistor TR is electrically connected to a transfer transistor drive line of the pixel drive line 10 (see FIG. 2).

As illustrated in FIG. 3, the readout circuit 15 includes, for example, a switching transistor FDG, a reset transistor RST, an amplification transistor AMP, and a selection transistor SEL as a plurality of pixel transistors. Such pixel transistors (FDG, RST, AMP, SEL) each include, for example, a MOSFET as a field effect transistor. The pixel transistors may be MISFETs.

Note that the selection transistor SEL and the switching transistor FDG may be omitted as necessary.

The switching transistor FDG has a source region (input end of the readout circuit 15) electrically connected to the charge holding region FD, and a drain region electrically connected to a source region of the reset transistor RST and a gate electrode of the amplification transistor AMP. Then, the switching transistor FDG has a gate electrode electrically connected to a switching transistor drive line of the pixel drive line 10 illustrated in FIG. 2.

The reset transistor RST has the source region electrically connected to the drain region of the switching transistor FDG, and a drain region electrically connected to a power line VDD. Then, the reset transistor RST has a gate electrode electrically connected to a reset transistor drive line of the pixel drive line 10 illustrated in FIG. 2.

The number of amplification transistors AMP is, for example, two in the first embodiment, but is not limited to two. Each of the two amplification transistors AMP has a source region electrically connected to a drain region of the selection transistor SEL, and a drain region electrically connected to the power line VDD. Then, each of the two amplification transistors AMP has the gate electrode electrically connected to the source region of the switching transistor FDG and the charge holding region FD. That is, the two amplification transistors AMP are connected in parallel.

The selection transistor SEL has a source region electrically connected to the vertical signal line 11, and the drain region electrically connected to the source region of the amplification transistor AMP. Then, the selection transistor SEL has a gate electrode electrically connected to a selection transistor drive line of the pixel drive line 10 illustrated in FIG. 2.

Note that, in a case where the selection transistor SEL is omitted, the source region of the amplification transistor AMP is electrically connected to the vertical signal line (VSL) 11. Furthermore, in a case where the switching transistor FDG is omitted, the source region of the reset transistor RST is electrically connected to the gate electrode of the amplification transistor AMP and the charge holding region FD.

When being turned on, the transfer transistor TR transfers the signal charge generated in the photoelectric conversion element PD to the charge holding region FD. When being turned on, the reset transistor RST resets the potential (signal charge) of the charge holding region FD to the potential of the power line VDD. The selection transistor SEL controls output timing of the pixel signal from the readout circuit 15.

The amplification transistor AMP generates a signal of a voltage corresponding to the level of the signal charge held in the charge holding region FD as the pixel signal. The amplification transistor AMP constitutes a source follower type amplifier, and outputs a pixel signal of a voltage corresponding to the level of the signal charge generated in the photoelectric conversion element PD. When the selection transistor SEL is turned on, the amplification transistor AMP amplifies the potential of the charge holding region FD, and outputs a voltage corresponding to the potential to the column signal processing circuit 5 via the vertical signal line (VSL) 11.

The switching transistor FDG controls charge accumulation of the charge holding region FD, and adjusts the multiplication factor of the voltage according to the potential multiplied by the amplification transistor AMP.

While the solid-state imaging device 1A according to the first embodiment is in operation, the signal charge generated in the photoelectric conversion element PD of the pixel 3 is held (accumulated) in the charge holding region FD via the transfer transistor TR of the pixel 3. Then, the signal charge held in the charge holding region FD is read out by the readout circuit 15 and applied to the gate electrode of the amplification transistor AMP of the readout circuit 15. A horizontal line selection control signal is supplied from a vertical shift register to the gate electrode of the selection transistor SEL of the readout circuit 15. Then, setting the selection control signal to a high (H) level brings the selection transistor SEL into conduction to allow a current corresponding to the potential of the charge holding region FD, amplified by the amplification transistor AMP, to flow to the vertical signal line 11. Furthermore, setting a reset control signal to be applied to the gate electrode of the reset transistor RST of the readout circuit 15 to the high (H) level brings the reset transistor RST into conduction to reset the signal charge accumulated in the charge holding region FD.

### <<Specific Configuration of Solid-State Imaging Device>>

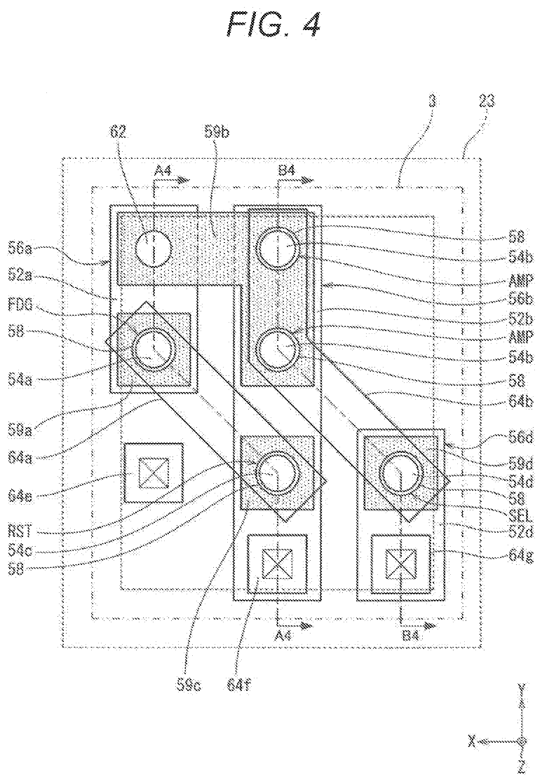

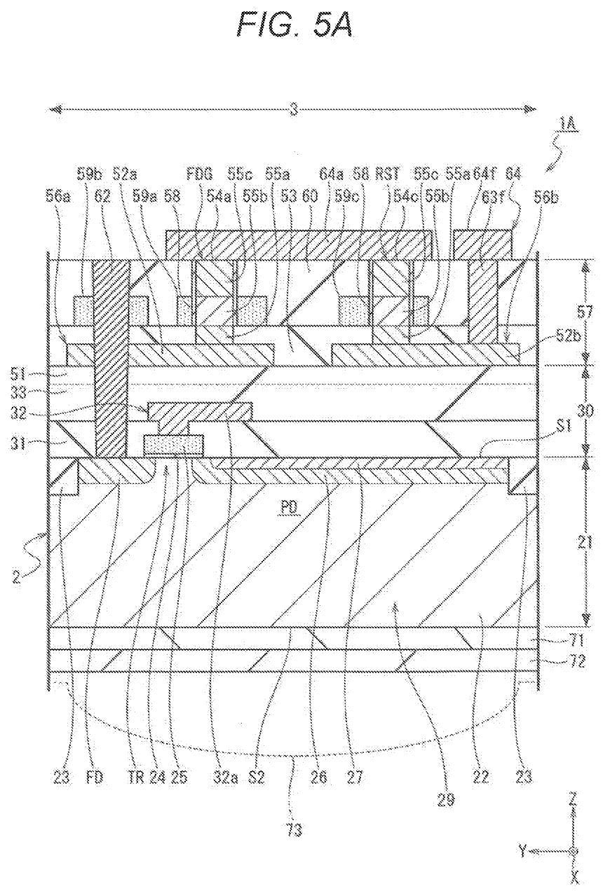

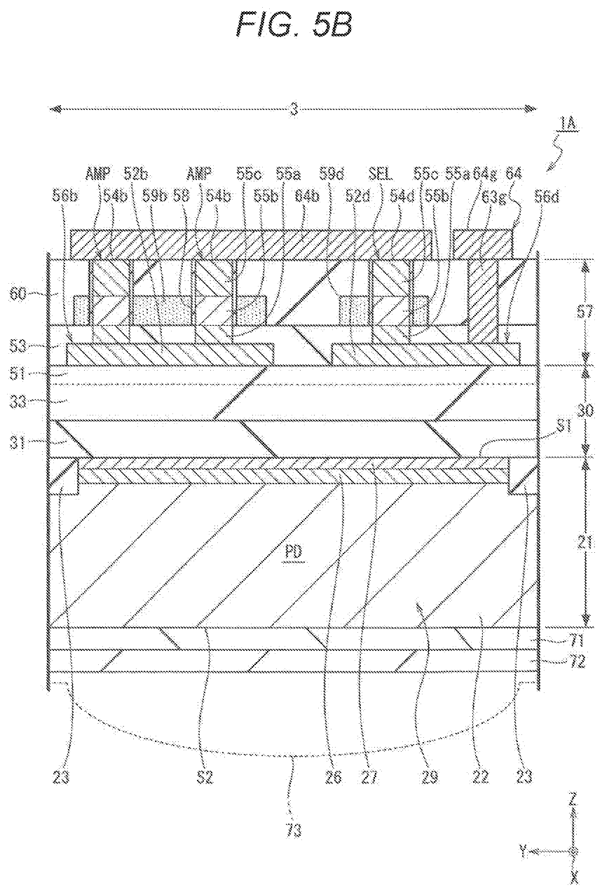

Next, a specific configuration of the semiconductor chip 2 (solid-state imaging device 1A) will be described with reference to FIGS. 4, 5A, and 5B. Note that FIGS. 4, 5A, and 5B are flipped upside down with respect to FIG. 1 to make the drawings easier to see, and illustration of a layer located above a wiring layer 64 to be described later is omitted.

### (Semiconductor Chip)

As illustrated in FIGS. 5A and 5B, the semiconductor chip 2 includes a semiconductor substrate 21 as a first semiconductor layer including, for example, single crystal silicon, and an insulating layer 30 provided on a first surface S1 side, the semiconductor substrate 21 having the first surface S1 and a second surface S2 on opposite sides in the thickness direction (Z direction). Furthermore, the semiconductor chip 2 further includes a semiconductor layer 57 as a second semiconductor layer provided on the first surface S1 side opposite from the first surface S1 side of the semiconductor substrate 21 with the insulating layer 30 interposed therebetween. Furthermore, the semiconductor chip 2 further includes an insulating film 53, an insulating film 60, and a wiring layer 64 provided on the first surface S1 side of the semiconductor substrate 21 with the insulating layer 30 interposed therebetween. That is, the solid-state imaging device 1A according to the first embodiment has a three-dimensional structure in which the semiconductor substrate 21 and the semiconductor layer 57 are stacked with the insulating layer 30 interposed therebetween.

Here, the first surface S1 of the semiconductor substrate 21 may be referred to as a principal surface or an element formation surface, and the second surface S2 may be referred to as a back surface or a light incident surface. In the first embodiment, light to be subjected to photoelectric conversion by the photoelectric conversion element PD impinges on the second surface S2 of the semiconductor substrate 21, so that the second surface S2 of the semiconductor substrate 21 may be referred to as a light incident surface.

Furthermore, as illustrated in FIGS. 5A and 5B, the semiconductor chip 2 further includes a planarizing film 71, a color filter 72, and a microlens 73 that are provided on the second surface S2 (light incident surface) of the semiconductor substrate 21 and stacked one by one from the second surface S2 side. The planarizing film 71 planarizes the second surface S2 side (light incident surface side) of the semiconductor substrate 21. The microlens 73 condenses light entering the semiconductor substrate 21. The color filter 72 color-separates light entering the semiconductor substrate 21. The color filter 72 and the microlens 73 are provided for each pixel 3.

### (Photoelectric Conversion Part and Isolation Region)

As illustrated in FIGS. 5A and 5B, the semiconductor substrate 21 is provided with a photoelectric conversion part 29 for each pixel 3. The photoelectric conversion part 29 is isolated by an isolation region 23 provided on the first surface S1 side of the semiconductor substrate 21. The isolation region 23 has, but not limited to, a shallow trench isolation (STI) structure in which, for example, an isolation groove part is formed in a surface layer part on the first surface S1 side of the semiconductor substrate 21 and a separation insulating film is selectively embedded in the isolation groove part. The isolation region 23 is disposed between the photoelectric conversion parts 29 adjacent to each other in the two-dimensional plane to isolate the first surface S1 side of the semiconductor substrate 21 for each pixel 3.

Here, as illustrated in FIG. 4, the isolation region 23 corresponding to one photoelectric conversion part 29 (one pixel 3) has a frame-like planar pattern (ring-like planar pattern) with a rectangular planar shape in plan view. Then, although not illustrated, the isolation region 23 corresponding to the entire pixel region 2A is a composite planar pattern having a grid-like planar pattern in which the isolation region 23 extending in the X direction and the isolation region 23 extending in the Y direction intersect in the frame-like planar pattern surrounding the periphery of the pixel region 2A in plan view.

### (Photoelectric Conversion Element, Transfer Transistor, and Charge Holding Region)

As illustrated in FIGS. 5A and 5B, each photoelectric conversion part 29 includes the photoelectric conversion element PD, the transfer transistor TR, and the charge holding region FD described above.

### (Photoelectric Conversion Element)

The photoelectric conversion element PD includes a p-type (first conductivity type) well region (semiconductor region) 22 provided in the photoelectric conversion part 29, an n-type (second conductivity type) semiconductor region 26 provided in a surface layer part of the well region 22 so as to form a pn junction with the well region 22, and a p-type semiconductor region 27 provided in a surface layer part of the semiconductor region 26 so as to form a pn junction with the semiconductor region 26.

### (Transfer Transistor)

As illustrated in FIG. 5A, the transfer transistor TR includes a gate insulating film 24 provided on the first surface S1 side of the semiconductor substrate 21, a gate electrode 25 provided on the first surface S1 side of the semiconductor substrate 21 with the gate insulating film 24 interposed therebetween, and the p-type well region 22 functioning as a channel formation region where a channel is formed. Furthermore, the transfer transistor TR includes the n-type semiconductor region 26 functioning as a source region and the charge holding region FD functioning as a drain region. The n-type semiconductor region 26 is formed, for example, in alignment with the gate electrode 25.

The gate insulating film 24 includes, for example, a silicon oxide film. The gate electrode 25 includes, for example, a polycrystalline silicon film doped with an impurity to make a resistance value lower.

### (Charge Holding Region)

The charge holding region FD includes an n-type semiconductor region formed, in the surface layer part on the first surface S1 side of the semiconductor substrate 21, in alignment with the gate electrode 25.

(Insulating layer)

As illustrated in FIGS. 5A and 5B, the insulating layer 30 includes an insulating film 31 provided on the first surface S1 side of the semiconductor substrate 21 so as to cover the gate electrode 25, a wiring layer 32 provided on the insulating film 31, an insulating film 33 provided on the insulating film 31 so as to cover the wiring layer 32, and an insulating film 51 bonded to a side of the insulating film 33 remote from the semiconductor substrate 21. The wiring layer 32 is provided with a plurality of wirings. In FIG. 5A, a wiring 32a electrically connected to the gate electrode 25 through an opening part of the insulating film 31 is illustrated.

The insulating film 31 includes, for example, any one of a silicon oxide (SiO) film, a silicon nitride (SiN) film, a silicon oxynitride (SiON) film, or a silicon carbonitride (SiCN) film, or a multilayer film including two or more of these films. The insulating films 33 and 51 each include, for example, a silicon oxide film. Each wiring including the wiring 32a of the wiring layer 32 includes, for example, a film of a metal such as copper (Cu) or an alloy mainly containing Cu.

### (Second Semiconductor Layer)

As illustrated in FIGS. 5A and 5B, the semiconductor layer 57 is provided on a side of the insulating layer 30 remote from the semiconductor substrate 21. Then, as illustrated in FIGS. 4, 5A, and 5B, the semiconductor layer 57 includes a first active region 56a, a second active region 56b, and a third active region 56d separated from each other on the insulating layer 30. Each of the first to third active regions 56a, 56b, and 56d is provided for each pixel 3.

Here, in FIGS. 5A and 5B, the first active region 56a is illustrated in FIG. 5A, the second active region 56b is illustrated in FIGS. 5A and 5B, and the third active region 56d is illustrated in FIG. 5B.

As illustrated in FIGS. 4 and 5A, the first active region 56a includes a base part 52a having an island shape and a protruding part 54a protruding upward from the base part 52a along a thickness direction (Z direction) of the base part 52a. The base part 52a extends, for example, in the Y direction in plan view (see FIG. 4).

As illustrated in FIGS. 4, 5A, and 5B, the second active region 56b includes a base part 52b having an island shape and protruding parts 54b (see FIG. 5B) and 54c (see FIG. 5A) protruding upward from the base part 52b along a thickness direction (Z direction) of the base part 52b. The base part 52b extends, for example, in the Y direction in plan view. For example, two protruding parts 54b are provided on one end side of the base part 52b apart from each other in the Y direction. The protruding part 54c is provided on the other end side of the base part 52b apart from the protruding parts 54b in the Y direction.

As illustrated in FIGS. 4 and 5B, the third active region 56d has a base part 52d having an island shape and a protruding part 54d protruding upward from the base part 52d along a thickness direction (Z direction) of the base part 52d. The base part 52d extends, for example, in the Y direction in plan view.

Each of the base parts 52a, 52b, and 52d is formed by, for example, reducing the thickness of the semiconductor substrate and then patterning the semiconductor substrate into a predetermined shape. Each of the base parts 52a, 52b, and 52d is provided on the same plane on the surface of the insulating layer 30.

As illustrated in FIGS. 5A and 5B, each of the protruding parts 54a, 54b, 54c, and 54d includes an n-type first semiconductor part 55a, a low-concentration semiconductor or i-type (intrinsic semiconductor, non-doped) second semiconductor part 55b, and an n-type third semiconductor part 55c stacked one by one from a corresponding base part (52a, 52b, 52d). The n-type first semiconductor part 55a is selectively epitaxially grown through an opening part of the insulating film 53 provided for each base part (52a, 52b, 52d), the insulating film 53 covering each base part (52a, 52b, 52d), and then the i-type second semiconductor part 55b and the n-type third semiconductor part 55c are selectively epitaxially grown in this order on the n-type first semiconductor part 55a, thereby forming each of the protruding parts 54a, 54b, 54c, and 54d. Each of the first semiconductor parts 55a is of the same conductivity type as a corresponding one of the base parts 52a, 52b, and 52d, and is electrically continuous with a corresponding one of the base parts 52a, 52b, and 52d. The second semiconductor part 55b may be of a p-type.

In each of the protruding parts 54a, 54b, 54c, and 54d, the n-type first and third semiconductor parts 55a and 55c function as a pair of main electrode regions that are the source region and the drain region of the pixel transistor, and the n-type second semiconductor part 55b functions as a channel formation region of the pixel transistor, which will be described in detail later.

Each base part (52a, 52b, 52d) and each protruding part (54a, 54b, 54c, 54d) include, for example, single crystal silicon. As illustrated in FIG. 4, the base parts 52a, 52b, and 52d extend in the Y direction and are provided side by side at predetermined intervals in the X direction. Each of the protruding parts 54a, 54b, 54c, and 54d is formed in, for example, a columnar shape, but may be formed in a prismatic shape.

As illustrated in FIGS. 5A and 5B, each of the first to third active regions 56a, 56b, and 56c is covered with the insulating film 53 except for a corresponding protruding part (54a, 54b, 54d). Then, the insulating film 60 is provided on the insulating film 53. The insulating film covers gate electrodes (59a, 59b, 59c, 59d) provided on the insulating film 53 and surrounds each protruding part (54a, 54b, 54d). The insulating film 53 and the insulating film 60 include, for example, one of a silicon oxide (SiO₂) film, a silicon nitride (Si₃N₄) film, a silicon oxynitride (SiON) film, or a silicon carbonitride (SiCN) film, or a multilayer film including two or more of these films.

### (Pixel Transistor)

As illustrated in FIGS. 4 and 5A, the first active region 56a is provided with, but not limited to, the switching transistor FDG as a first field effect transistor, for example. As illustrated in FIGS. 4, 5A, and 5B, the second active region 56b is provided with, but not limited to, the two amplification transistors AMP as second field effect transistors, for example. Then, the second active region 56b is further provided with the reset transistor RST. As illustrated in FIGS. 4 and 5B, the third active region 56d is provided with the selection transistor SEL. The two amplification transistors AMP are connected in parallel.

### (Switching Transistor)

As illustrated in FIGS. 4 and 5A, the switching transistor FDG includes the second semiconductor part 55b provided in the protruding part 54a of the first active region 56a and functioning as a channel formation region in which a channel is formed, and the gate electrode 59a disposed outside the second semiconductor part 55b with a gate insulating film 58 interposed therebetween. Furthermore, the switching transistor FDG further includes a pair of main electrode regions functioning as a source region and a drain region. One of the pair of main electrode regions includes the base part 52a and the first semiconductor part 55a provided in the protruding part 54a, and functions as, for example, the source region. Then, the other of the pair of main electrode regions includes the third semiconductor part 55c provided in the protruding part 54a, and functions as, for example, the drain region. That is, the switching transistor FDG has a vertical structure in which the pair of main electrode regions (the base part 52a and the first semiconductor part 55a, and the third semiconductor part 55c) are provided in the first active region 56a apart from each other in the protruding direction of the protruding part 54a with the channel formation region (the second semiconductor part 55b) interposed therebetween. The gate electrode 59a is provided to surround the second semiconductor part of the protruding part 54a in plan view.

### (Amplification Transistor)

As illustrated in FIGS. 4 and 5B, each of the two amplification transistors AMP includes the second semiconductor part 55b provided in the protruding part 54b of the second active region 56b and functioning as a channel formation region in which a channel is formed, and the gate electrode 59b disposed outside the second semiconductor part 55b with the gate insulating film 58 interposed therebetween. Furthermore, each of the two amplification transistors AMP further includes a pair of main electrode regions functioning as a source region and a drain region. One of the pair of main electrode regions includes the third semiconductor part 55c provided in the protruding part 54b, and functions as, for example, the source region. Then, the other of the pair of main electrode regions includes the base part 52b, and the first semiconductor part 55a provided in the protruding part 54b, and functions as, for example, the drain region. That is, each of the two amplification transistors AMP has a vertical structure in which the pair of main electrode regions (the third semiconductor part 55c, and the base part 52a and the first semiconductor part 55a) are provided in the second active region 56b apart from each other in the protruding direction of the protruding part 54b with the channel formation region (the second semiconductor part 55b) interposed therebetween. The gate electrode 59b is provided to surround the second semiconductor part 55b of each of the two protruding parts 54b in plan view.

### (Reset Transistor)

As illustrated in FIGS. 4 and 5A, the reset transistor RST includes the second semiconductor part 55b provided in the protruding part 54c of the second active region 56b and functioning as a channel formation region in which a channel is formed, and the gate electrode 59c disposed outside the second semiconductor part 55b with the gate insulating film 58 interposed therebetween. Furthermore, the reset transistor RST further includes a pair of main electrode regions functioning as a source region and a drain region. One of the pair of main electrode regions includes the third semiconductor part 55c provided in the protruding part 54c, and functions as, for example, the source region. Then, the other of the pair of main electrode regions includes the base part 52b, and the first semiconductor part 55a provided in the protruding part 54c, and functions as, for example, the drain region. That is, the reset transistor RST has a vertical structure in which the pair of main electrode regions (the third semiconductor part 55c, and the base part 52b and the first semiconductor part 55a) are provided in the second active region 56b apart from each other in the protruding direction of the protruding part 54c with the channel formation region (the second semiconductor part 55b) interposed therebetween. The gate electrode 59c is provided to surround the second semiconductor part 55b of the protruding part 54c in plan view.

### (Selection Transistor)

As illustrated in FIGS. 4 and 5B, the selection transistor SEL includes the second semiconductor part 55b provided in the protruding part 54d of the third active region 56d and functioning as a channel formation region in which a channel is formed, and the gate electrode 59d disposed outside the second semiconductor part 55b with the gate insulating film 58 interposed therebetween. Furthermore, the selection transistor SEL further includes a pair of main electrode regions functioning as a source region and a drain region. One of the pair of main electrode regions includes the base part 52d and the first semiconductor part 55a provided in the protruding part 54d, and functions as, for example, the source region. Then, the other of the pair of main electrode regions includes the third semiconductor part 55c provided in the protruding part 54d, and functions as, for example, the drain region. That is, the selection transistor SEL has a vertical structure in which the pair of main electrode regions (the base part 52d and the first semiconductor part 55a, and the third semiconductor part 55c) are provided in the third active region 56d apart from each other in the protruding direction of the protruding part 54d with the channel formation region (the second semiconductor part 55b) interposed therebetween. The gate electrode 59d is provided to surround the second semiconductor part 55b of the protruding part 54d in plan view.

The gate insulating film 58 includes, for example, a silicon oxide film. Each of the gate electrodes 59a, 59b, 59c, and 59d is formed in the same process, and includes, for example, a polycrystalline silicon film doped with an impurity to make resistance lower. The gate insulating film 58 and the gate electrode (59a, 59b, 59c, 59d) may include High K or Metal Gate.

### (Sharing of Gate Electrode)

As illustrated in FIGS. 4, 5A, and 5B, the two amplification transistors AMP share the gate electrode 59b. The gate electrode 59b has a first portion that surrounds the second semiconductor part 55b of each of the two protruding parts 54b and extends along a longitudinal direction (Y direction) of the second active region 56b, and a second portion that extends from the first portion toward the first active region 56a and is aligned with the first active region 56a in plan view. That is, the gate electrode 59b is routed over the first active region 56a and the second active region 56b in the two-dimensional plane.

### (Sharing of Main Electrode Region)

As illustrated in FIGS. 4, 5A, and 5B, the two amplification transistors AMP and the reset transistor RST share the base part 52b functioning as the drain region (the other main electrode region).

### (Wiring Layer)

As illustrated in FIGS. 4, 5A, and 5B, the wiring layer 64 is provided on the insulating film 60. In the wiring layer 64, wirings 64a, 64b, 64e, 64f, and 64g are provided. Although not illustrated for convenience sake, such wirings 64a, 64b, 64e, 64f, and 64g are covered with an insulating film provided on the insulating film 60.

As illustrated in FIGS. 4 and 5A, the third semiconductor part 55c of the protruding part 54a is directly connected to one end side of the wiring 64a provided on the insulating film 60 to be electrically continuous with the wiring 64a. The third semiconductor part 55c of the protruding part 54c is directly connected to the other end side of the wiring 64a to be electrically continuous with the wiring 64a. That is, the drain region of the switching transistor FDG (the third semiconductor part 55c of the protruding part 54a) and the source region of the reset transistor RST (the third semiconductor part 55c of the protruding part 54c) are electrically connected through the wiring 64a.

The wiring 64a is routed such that the one end side is aligned with the protruding part 54a of the first active region 56a and the other end side is aligned with the protruding part 54c of the second active region 56b in plan view. That is, the wiring 64a extends over the first active region 56a and the second active region 56b in the two-dimensional plane of the semiconductor chip 2.

As illustrated in FIGS. 4 and 5B, the third semiconductor part 55c of each of the two protruding parts 54b is directly connected to one end side of the wiring 64b provided on the insulating film 60 to be electrically continuous with the wiring 64b. The third semiconductor part 55c of the protruding part 54d is directly connected to the other end side of the wiring 64b to be electrically continuous with the wiring 64b. That is, the source region of each of the two amplification transistors AMP (the third semiconductor part 55c of the protruding part 54b) and the drain region of the selection transistor SEL (the third semiconductor part 55c of the protruding part 54d) are electrically connected through the wiring 64b.

The wiring 64b is routed such that the one end side is aligned with the two protruding parts 54b of the second active region 56b and the other end side is aligned with the protruding part 54d of the third active region 56d in plan view. That is, the wiring 64b extends over the second active region 56b and the third active region 56d in the two-dimensional plane of the semiconductor chip 2.

As illustrated in FIGS. 4 and 5A, the base part 52b of the second active region 56b is electrically connected to the wiring 64f provided on the insulating film 60 through a contact electrode (conductive plug, via wiring) 63f embedded in the insulating films 53 and 60. Then, although not illustrated in detail, the wiring 64f is electrically connected to the power line VDD illustrated in FIG. 3. That is, the drain region of each of the two amplification transistors AMP and the drain region of the reset transistor RST are electrically connected to the power line VDD.

As illustrated in FIGS. 4 and 5B, the base part 52d of the third active region 56d is electrically connected to the wiring 64g provided on the insulating film 60 through a contact electrode (conductive plug, via wiring) 63g embedded in the insulating films 53 and 60. Then, although not illustrated in detail, the wiring 64g is electrically connected to the vertical signal line 11 illustrated in FIG. 3.

Note that, although not illustrated in detail, the wiring 64e illustrated in FIG. 4 is electrically connected to the wiring 32a illustrated in FIG. 5A. Then, the wiring 64a is electrically connected to the transfer transistor drive line of the pixel drive line 10 illustrated in FIG. 2.

### (Conductive Path)

As illustrated in FIGS. 4 and 5A, the semiconductor chip 2 further includes a contact electrode (conductive plug, via wiring, through via) 62 extending in the Z direction through the semiconductor substrate 21 as the first semiconductor layer and the semiconductor layer 57 as the second semiconductor layer.

The contact electrode 62 is directly connected to the base part 52a of the first active region 56a functioning as the source region that is any one of the pair of main electrode regions of the switching transistor (first field effect transistor) FDG. Furthermore, the contact electrode 62 is directly connected to the gate electrode 59b of the amplification transistors (second field effect transistors) AMP and the charge holding region FD of the semiconductor substrate 21. Then, the contact electrode 62 is electrically continuous with the base part 52a, the gate electrode 59b, and the charge holding region FD. As illustrated in FIG. 3, the contact electrode 62 forms a conductive path 65 electrically connecting the source region (base part 52a) of the switching transistor FDG, the gate electrode (59b) of the amplification transistors AMP, and the charge holding region FD.

In the first embodiment, the gate electrode 59b of the amplification transistors AMP, the base part 52a of the first active region 56a that is the source region of the switching transistor FDG, and the charge holding region FD are aligned with each other in plan view. Then, the contact electrode 62 extends linearly along the thickness direction (Z direction) of the semiconductor substrate 21 from the insulating film 60 side to the charge holding region FD through the gate electrode 59b and the base part 52a of the first active region 56a, and is directly connected to the gate electrode 59b, the base part 52a, and the charge holding region FD.

As the contact electrode 62, and the contact electrodes 63f and 63g described above, it is possible to use a high melting point metal material such as titanium (Ti), tungsten (W), cobalt (Co), or molybdenum (Mo), and for example, tungsten (W) is used.

A wiring that is provided in the wiring layer 64 located above the semiconductor layer 57 and extends in a horizontal direction (two-dimensional direction) is not connected to the contact electrode 62. That is, the conductive path 65 does not include the wiring provided in the wiring layer 64 located on the semiconductor layer 57.

### <<Method for Manufacturing Solid-State Imaging Device>>

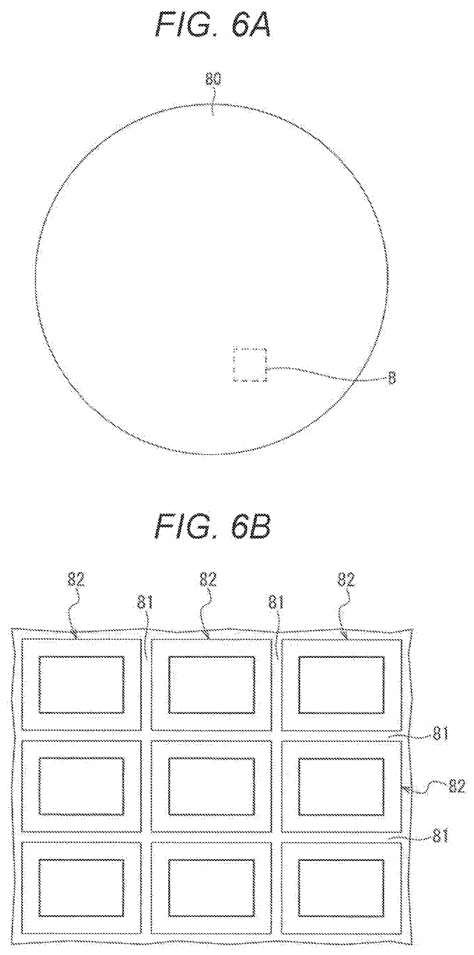

Next, a method for manufacturing the solid-state imaging device 1A according to the first embodiment will be described with reference to FIGS. 6A and 6B and FIGS. 7A to 16B.

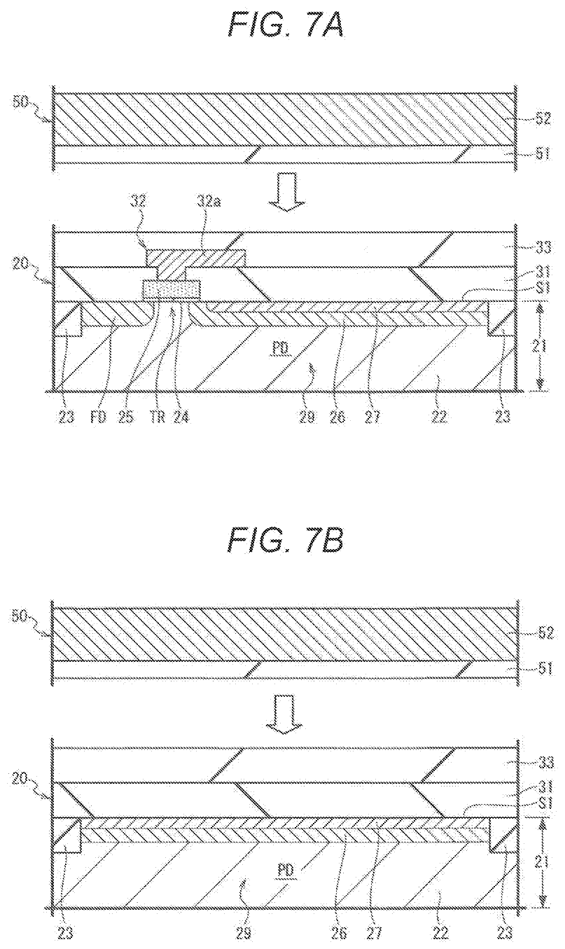

FIG. 6A is a diagram illustrating a planar configuration of a semiconductor wafer, and FIG. 6B is an enlarged view of a region B in FIG. 6A, illustrating a configuration of a chip formation region. Furthermore, FIGS. 7A to 16B are schematic cross-sectional views for describing the method for manufacturing the solid-state imaging device 1A.

The cross sections illustrated in FIGS. 7A, 8A, 9A, 10A, 11A, 12A, 13A, 14A, 15A, and 16A are cross sections taken along a line A4-A4 illustrated in FIG. 4. Furthermore, the cross sections illustrated in FIGS. 7B, 8B, 9B, 10B, 11B, 12B, 13B, 14B, 15B, and 16B are cross sections taken along a line B4-B4 illustrated in FIG. 4. Note that, in the description of the method for manufacturing the solid-state imaging device 1A according to the first embodiment, the photoelectric conversion part 29 (photoelectric conversion element PD), the transfer transistor TR, the charge holding region FD, and the pixel transistor (FDG, RST, AMP, SEL) included in the pixel unit PU will be mainly described.

Here, as illustrated in FIGS. 6A and 6B, the solid-state imaging device 1A is manufactured in each of a plurality of chip formation regions 82 set in advance in a semiconductor wafer 80. The plurality of chip formation regions 82 is each defined by a scribe line 81 and is arranged in a matrix. In FIG. 6B, nine chip formation regions 82 arranged in a three-by-three matrix in a row direction and a column direction are illustrated. Then, the plurality of chip formation regions 82 is separated, along the scribe line 81, into single chips, thereby forming the semiconductor chip 2 on which the solid-state imaging device 1A is mounted. The chip formation regions 82 are separated into single chips after the solid-state imaging device 1A is formed in each chip formation region 82 by a manufacturing process to be described below. Note that the scribe line 81 is not physically formed.

First, a first semiconductor base 20 and a second semiconductor base 50 illustrated in FIGS. 7A and 7B are prepared.

The first semiconductor base 20 illustrated in FIGS. 7A and 7B includes the semiconductor substrate 21, and further includes the p-type well region 22, the isolation region 23, the photoelectric conversion part 29, the transfer transistor TR, the charge holding region FD, and the like formed in the semiconductor substrate 21. Furthermore, the first semiconductor base 20 further includes the insulating film 31, the wiring layer 32, the insulating film 33, and the like formed on the first surface S1 side of the semiconductor substrate 21. As the semiconductor substrate 21, for example, a single crystal silicon substrate is used. The isolation region 23 has, for example, an STI structure. The photoelectric conversion part 29 includes the p-type well region 22, the n-type semiconductor region 26, and the p-type semiconductor region 27. The transfer transistor TR includes the gate insulating film 24, the gate electrode 25, the p-type well region 22 functioning as the channel formation region, the n-type semiconductor region 26 functioning as the source region, and the charge holding region FD functioning as the drain region. The charge holding region FD includes an n-type semiconductor region.

The well region 22, the isolation region 23, the photoelectric conversion part 29, the transfer transistor TR, the charge holding region FD, and the like are formed for each pixel 3 illustrated in FIG. 1. Furthermore, the pixel 3, the insulating film 31, the wiring layer 32, the insulating film 33, and the like are formed for each chip formation region 82 illustrated in FIG. 6B. Then, in each chip formation region 82, the pixel region 2A and the peripheral region 2B illustrated in FIG. 1 are formed.

Note that the planarizing film 71, the color filter 72, and the microlens 73 illustrated in FIGS. 5A and 5B are not yet formed.

On the other hand, the second semiconductor base 50 illustrated in FIGS. 7A and 7B includes a semiconductor substrate 52 and the insulating film 51 disposed on a first surface of the semiconductor substrate 52, the semiconductor substrate 52 having the first surface and a second surface on opposite sides. As the semiconductor substrate 52, for example, an n-type single crystal silicon substrate is used. The insulating film 51 includes, for example, a silicon oxide film.

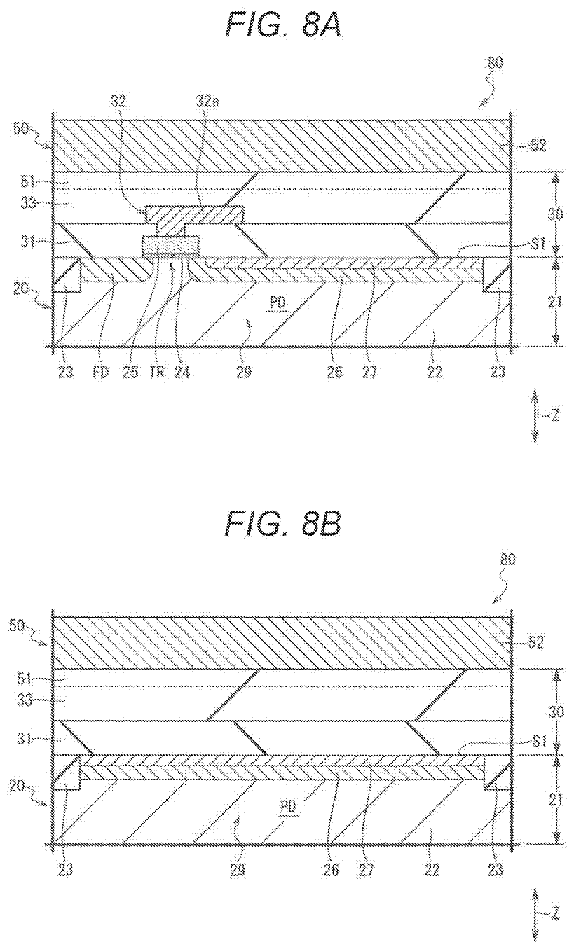

Next, the insulating film 33 of the first semiconductor base 20 and the insulating film 51 of the second semiconductor base 50 are placed to face each other as illustrated in FIGS. 7A and 7B, and then, with the first semiconductor base 20 and the second semiconductor base 50 facing each other, the first semiconductor base 20 and the second semiconductor base 50 are bonded together as illustrated in FIGS. 8A and 8B. This bonding can be made by bonding the insulating film 33 and the insulating film 51 with, for example, an adhesive or plasma.

In this bonding process, the insulating layer 30 including the insulating film 33 and the insulating film 51 is formed between the semiconductor substrate 21 and the semiconductor substrate 52. Furthermore, the semiconductor wafer 80 including the semiconductor substrates 21 and 52 stacked on top of each other in the thickness direction (Z direction) with the insulating layer 30 interposed therebetween is formed.

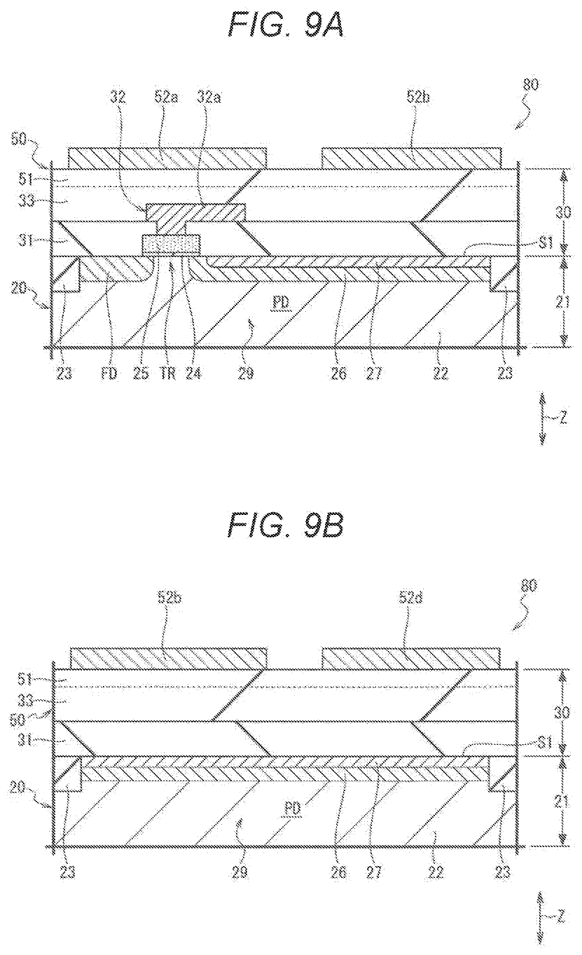

Next, the first surface side of the semiconductor substrate 52 is ground and polished by, for example, chemical mechanical polishing (CMP) or the like to make the semiconductor substrate 52 thinner, and then the semiconductor substrate 52 is patterned to form the n-type base part 52a, the n-type base part 52b, and the n-type base part 52d on the insulating layer 30 as illustrated in FIGS. 9A and 9B. Each of the base parts 52a, 52b, and 52d is formed for each pixel 3. Furthermore, referring to FIG. 4, the base parts 52a, 52b, and 52d each extend in the Y direction and are provided side by side at predetermined intervals in the X direction. The semiconductor substrate 52 before being ground and polished has a thickness of, for example, about 600 μm, but the semiconductor substrate 52 is thinned to, for example, about 0.1 to 0.5 μm. The patterning of the semiconductor substrate 52 is performed by photolithography and anisotropic etching. The base parts 52a, 52b, and 52d are formed in the same plane on the surface of the insulating layer 30.

As illustrated in FIG. 9A, the base part 52a is formed to be partially aligned with the charge holding region FD of the lower semiconductor substrate 21 in plan view.

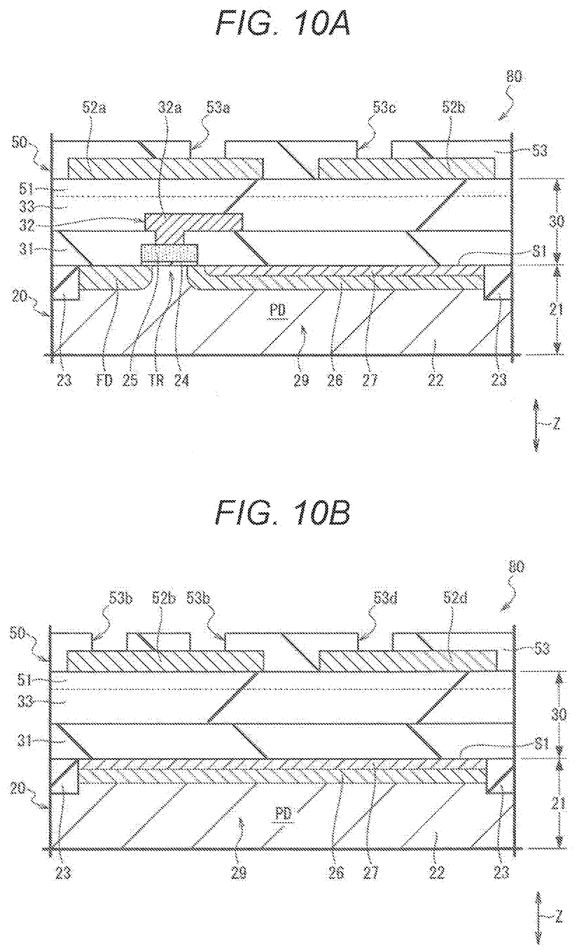

Next, the insulating film 53 covering each of the base parts 52a, 52b, and 52d is formed on the insulating layer 30, and then an opening part 53a that selectively exposes a part of the base part 52a, opening parts 53b and 53c that selectively expose a part of the base part 52b, and an opening part 53d that selectively exposes a part of the base part 52d are formed in the insulating film 53 as illustrated in FIGS. 10A and 10B. The insulating film 53 is formed, for example, by depositing a silicon oxide film all over the insulating layer 30 by CVD. Each of the opening parts 53a, 53b, 53c, and 53d is formed by well-known photolithography and anisotropic etching. Each of the base parts 52a, 52b, and 52d functions as one of the pair of main electrode regions that are the source region and the drain region of the pixel transistor (FDG, RST, AMP, SEL).

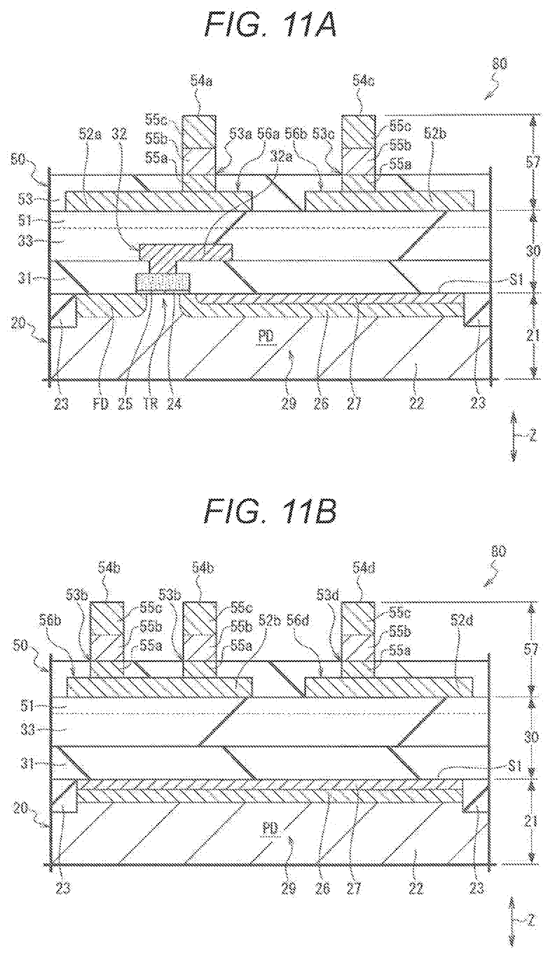

Next, as illustrated in FIGS. 11A and 11B, the protruding part 54a is formed on the base part 52a through the opening part 53a of the insulating film 53, the protruding parts 54b and 54c are formed on the base part 52b through the opening parts 53b and 53c of the insulating film 53, and the protruding part 54d is formed on the base part 52d through the opening part 53d of the insulating film 53. Each of the protruding parts 54a, 54b, 54c, and 54d includes the n-type first semiconductor part 55a, the i-type second semiconductor part 55b, and the n-type third semiconductor part 55c stacked one by one from each of the base parts 52a, 52b, and 52d.

The n-type first semiconductor part 55a is selectively epitaxially grown on each of the base parts 52a, 52b, 52c, and 52d through each of the opening parts 53a, 53b, 53c, and 53d provided in the insulating film 53, and then the i-type second semiconductor part 55b and the n-type third semiconductor part 55c are selectively epitaxially grown on each of the n-type first semiconductor parts 54a in this order, thereby forming each of the protruding parts 54a, 54b, 54c, and 54d. Each of the protruding parts 54a, 54b, 54c, and 54d includes, for example, single crystal silicon.

In each of the protruding parts 54a, 54b, 54c, and 54d, the n-type first and third semiconductor parts 55a and 55c function as the pair of main electrode regions that are the source region and the drain region of the pixel transistor (FDG, RST, AMP, SEL), and the n-type second semiconductor part 55b functions as the channel formation region of the pixel transistor (FDG, RST, AMP, SEL).

Each of the protruding parts 54a, 54b, 54c, and 54d is formed in, for example, a columnar shape, but may be formed in a prismatic shape.

In this process, the first active region 56a including the base part 52a and the protruding part 54a, the second active region 56b including the base part 52b and the protruding parts 54b and 54c, and the third active region 56d including the base part 52c and the protruding part 54d are formed on the insulating layer 30.

Furthermore, in this process, the semiconductor layer 57 including the first to third active regions 56a, 56b, and 56d is formed on the insulating layer 30.

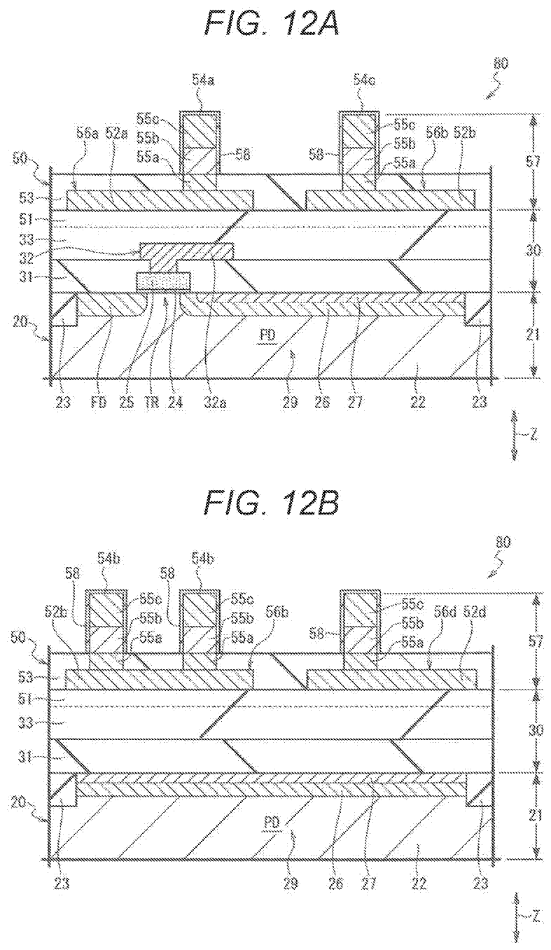

Next, in each of the protruding parts 54a, 54b, 54c, and 54d, the gate insulating film 58 is formed on the side wall and the upper wall of the second semiconductor part 55b and the third semiconductor part 55c protruding from the insulating film 53 as illustrated in FIGS. 12A and 12B. A surface of a portion (the second and third semiconductor parts 55b and 55c) of each of the protruding parts 54a, 54b, 54c, and 54d protruding from the insulating film 53 is oxidized by thermal oxidation treatment to form the gate insulating film 58.

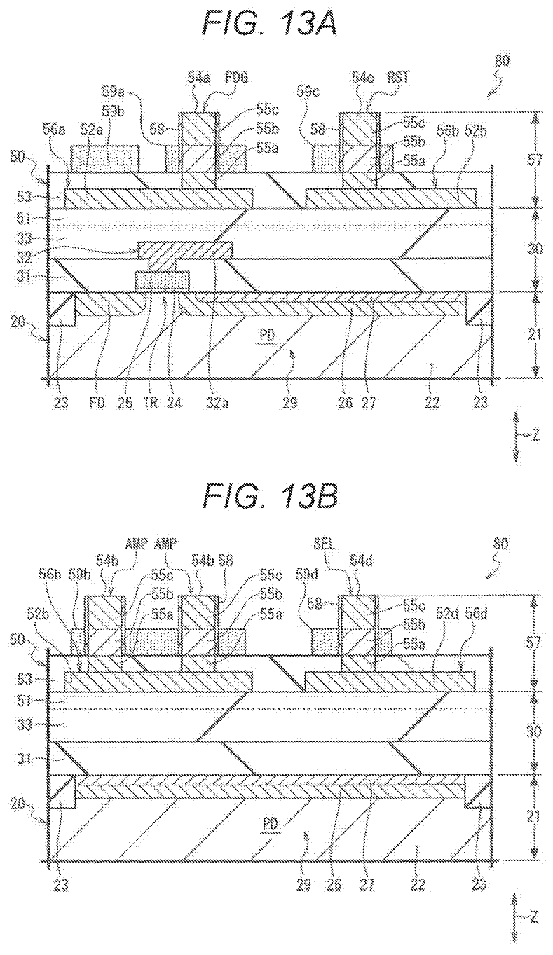

Next, as illustrated in FIGS. 13A and 13B, the gate electrodes 59a, 59b, 59c, and 59d are each formed outside the second semiconductor part 55b of a corresponding one of the protruding parts 54a, 54b, 54c, and 54d with the gate insulating film 58 interposed therebetween. Each of the gate electrodes 59a, 59b, 59c, and 59d can be formed by depositing, for example, a polycrystalline silicon film all over the insulating film 53 including each protruding part (54a, 54b, 54c, and 54d) by CVD, and then patterning the polycrystalline silicon film into a predetermined shape. The polycrystalline silicon film is doped with an impurity to make a resistance value lower during or after the deposition. Each of the gate electrodes 59a, 59b, 59c, and 59d is formed on the surface of the insulating film 53.

Referring to FIG. 4, the gate electrode 59a is formed to surround the second semiconductor part 55b of the protruding part 54a in plan view. The gate electrode 59b includes a first portion that surrounds the second semiconductor part 55b of each of the two protruding parts 54b and extends along the longitudinal direction (Y direction) of the second active region 56b, and a second portion that extends from the first portion toward the first active region 56a and is aligned with the first active region 56a in plan view, and is formed over the first active region 56a and the second active region 56b in the two-dimensional plane. The gate electrode 59c is formed to surround the second semiconductor part 55b of the protruding part 54c in plan view. The gate electrode 59d is formed to surround second semiconductor part 55b of the protruding part 54d in plan view.

In this process, the switching transistor FDG is formed in the first active region 56a, the two amplification transistors AMP and the reset transistor RST are formed in the second active region 56b, and the selection transistor SEL is formed in the third active region 56d.

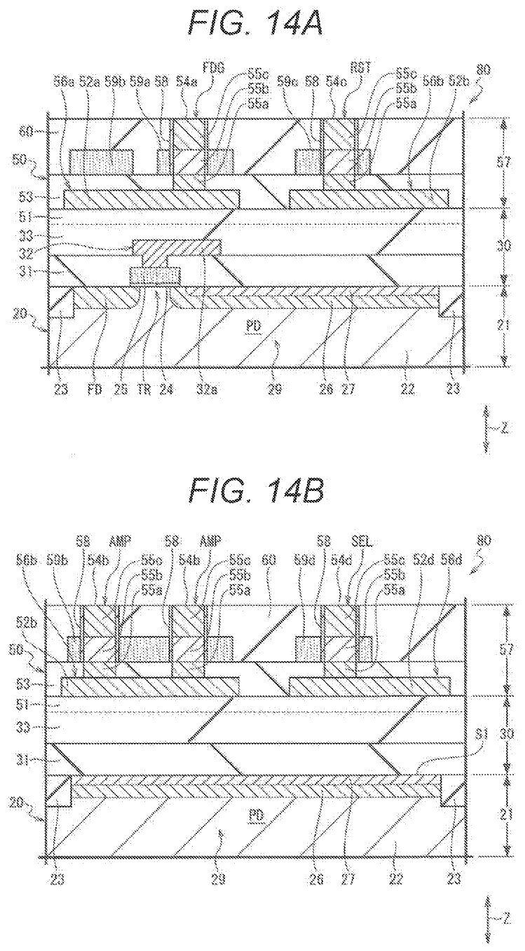

Next, the insulating film 60 including, for example, a silicon oxide film is formed all over the insulating film 53 by CVD to cover the protruding parts 54a, 54b, 54c, and 54d and the gate electrodes 59a, 59b, 59c, and 59d, and thereafter, the surface of the insulating film 60 is planarized by, for example, CMP to expose the top surface of the third semiconductor part 55c of each of the protruding parts 54a, 54b, 54c, and 54d as illustrated in FIGS. 14A and 14B.

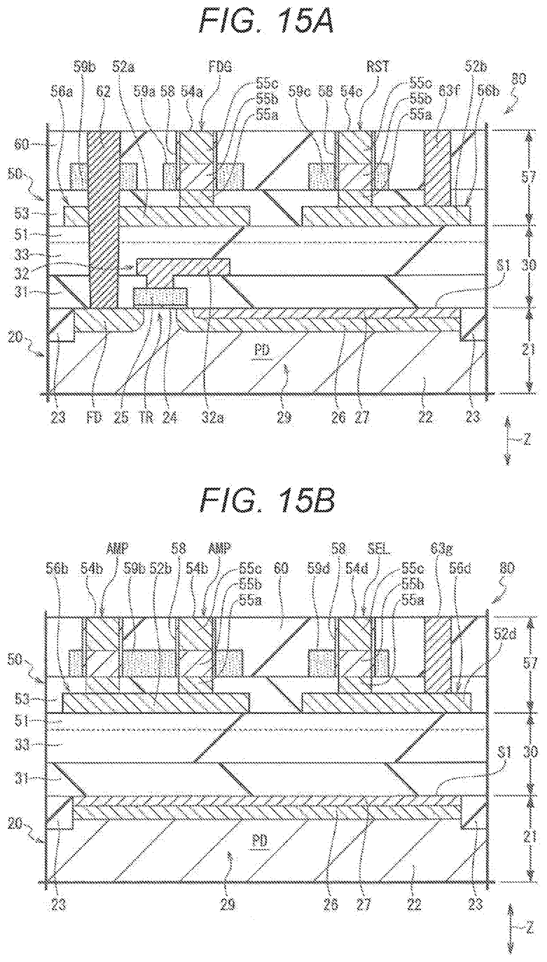

Next, as illustrated in FIG. 15A, the contact electrode 62 that extends through the semiconductor substrate 21 and the semiconductor layer 57 and is directly connected to the gate electrode 59b of the amplification transistors AMP, the base part 52a of the first active region 56a functioning as the source region of the switching transistor FDG, and the charge holding region FD is formed. Furthermore, as illustrated in FIG. 15A, the contact electrode 63f electrically connected to the base part 52b of the second active region 56b functioning as the drain region of the reset transistor RST is formed, and as illustrated in FIG. 15B, the contact electrode 63g electrically connected to the base part 52d of the third active region 56d functioning as the source region of the selection transistor SEL is formed.

The contact electrode 62 can be formed by forming a connecting hole that extends from the surface side of the insulating film 60 to the surface of the charge holding region FD through the insulating film 60, the gate electrode 59b, the insulating film 53, the base part 52a of the first active region 56a, the insulating layer 30, and the like, and then embedding a conductive material in the connecting hole.

The contact electrode 63f can be formed by forming a connecting hole that extends from the surface side of the insulating film 60 to the surface of the base part 52b of the second active region 56b through the insulating film 60, the insulating film 53, and the like, and then embedding a conductive material in the connecting hole. The contact electrode 63g can be formed by forming a connecting hole that extends from the surface side of the insulating film 60 to the surface of the base part 52d of the third active region 56d through the insulating film 60, the insulating film 53, and the like, and then embedding a conductive material in the connecting hole. The contact electrodes 63f and 63g can be formed in the same process. Furthermore, the process of forming the contact electrodes 63f and 63g can be performed before and after the process of forming the contact electrode 62. As the conductive material of each of the contact electrodes 62, 63f, and 63g, for example, tungsten (W) can be used.

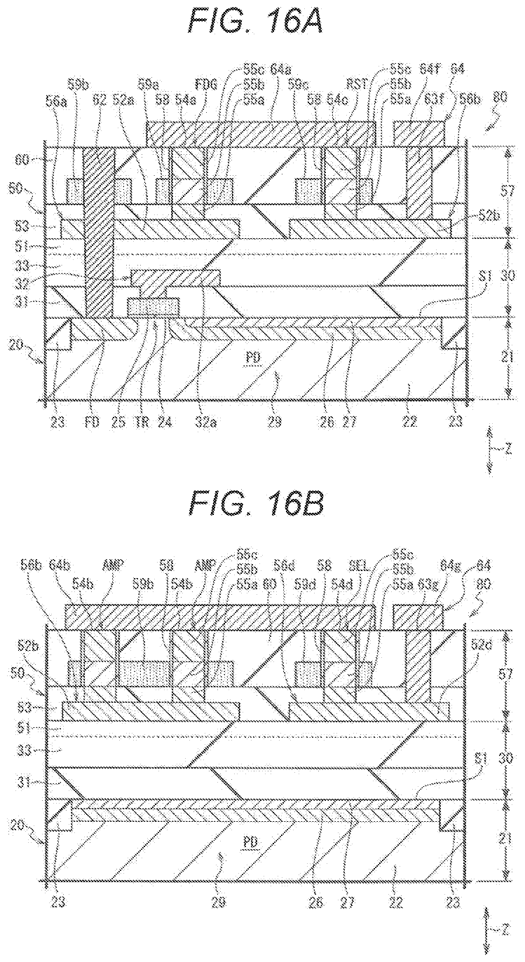

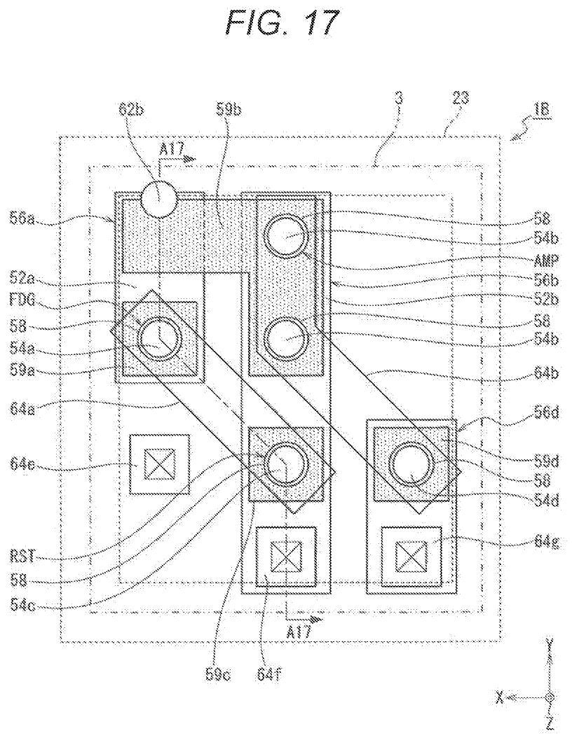

Next, as illustrated in FIGS. 16A and 16B, the wiring layer 64 including the wirings 64a, 64b, 64e, 64f, and 64g is formed on the insulating film 60. The wirings 64a, 64b, 64e, 64f, and 64g can be formed by depositing a conductive film as a wiring material on the insulating film 60 by, for example, sputtering, and then patterning the conductive film into a predetermined shape by well-known photolithography and etching.

The wiring 64a has one end side electrically connected to the third semiconductor part 55c of the protruding part 54a of the first active region 56a (the drain region side of the switching transistor FDG), and the other end side electrically connected to the third semiconductor part 55c of the protruding part 54c of the second active region 56b (the source region side of the reset transistor RST). The wiring 64b has one end side electrically connected to the third semiconductor part 55c of each of the two protruding parts 54b of the second active region 56b (the source region side of the amplification transistor AMP), and the other end side electrically connected to the third semiconductor part 55c of the protruding part 55d of the third active region 56d (the drain region side of the selection transistor SEL). The wiring 64f is electrically connected to the base part 52b of the second active region 56b (the drain region side of the reset transistor RST) through the contact electrode 63f. The wiring 64g is electrically connected to the base part 52d of the third active region 56d (the source region side of the selection transistor SEL) through the contact electrode 63g.

Note that, referring to FIG. 4, although not illustrated in FIGS. 16A and 16B, the wiring layer 64 further includes the wiring 64e. The wiring 64e is electrically connected to the contact electrode that extends from the surface of the insulating film 60 to the surface of the wiring 32a through the insulating films 60, 53, 51, 33, and the like, and the gate electrode 25 of the transfer transistor TR through the wiring 32a.

In this process, the readout circuit 15 including the pixel transistor (FDG, RST, AMP, SEL) is formed. Furthermore, the pixel unit PU including the pixel 3 and the readout circuit 15 is formed.

Furthermore, in this process, the conductive path 65 electrically connecting the source region of the switching transistor FDG, the gate electrode 59b of the amplification transistors AMP, and the charge holding region FD only by the contact electrode 62 is formed.

Next, the planarizing film 71, the color filter 72, the microlens 73, and the like are formed one by one on the second surface S2 side (light incident surface side) of the semiconductor substrate 21.

In this process, the solid-state imaging device 1A including the photoelectric conversion part, the transfer transistor, and the charge holding region formed in the semiconductor substrate and including the pixel transistor formed in the semiconductor layer 57 is almost completed.

Furthermore, in this process, the semiconductor wafer 80 illustrated in FIGS. 6A and 6B is almost completed. The solid-state imaging device 1A is formed in each chip formation region 82 of the semiconductor wafer 80.

Thereafter, the plurality of chip formation regions 82 of the semiconductor wafer 80 illustrated in FIG. 6B is separated, along the scribe line 81, into single chips, thereby forming the semiconductor chip 2 on which the solid-state imaging device 1A is mounted.

### <<Effects of First Embodiment>>

Next, main effects of the first embodiment will be described.

In a solid-state imaging device in the related art, a charge holding region provided in a first semiconductor layer and a pixel transistor provided in a second semiconductor layer are electrically connected by a conductive path including a contact electrode that extends in a vertical direction through the first and second semiconductor layers and a wiring that is provided in a wiring layer on the second semiconductor layer and extends in a horizontal direction. In such a conductive path in the related art, wiring capacitance (parasitic capacitance) is added to each of the contact electrode and the wiring. The wiring capacitance causes a decrease in photoelectric conversion rate.

On the other hand, as illustrated in FIG. 5A, the solid-state imaging device 1A according to the first embodiment includes the contact electrode 62 that extends in the vertical direction (Z direction) through the semiconductor substrate 21 and the semiconductor layer 57 and is directly connected to the source region (the base part 52a of the first active region 56a) of the switching transistor FDG, the gate electrode 59b of the amplification transistors AMP, and the charge holding region FD. That is, the solid-state imaging device 1A according to the first embodiment electrically connects the charge holding region FD provided in the semiconductor substrate 21 as the first semiconductor layer, and the source region of the switching transistor FDG and the gate electrode 59b of the amplification transistors AMP provided in the semiconductor layer 57 as the second semiconductor layer by the conductive path 65 (see FIG. 3) including the contact electrode 62 that extends in the vertical direction (Z direction) and not including the wiring that is provided in the wiring layer and extends in the horizontal direction (two-dimensional plane direction). The conductive path 65 does not include the wiring extending in the horizontal direction, so that it is possible to reduce the wiring capacitance as compared with the conductive path in the related art including the contact electrode extending in the vertical direction and the wiring extending in the horizontal direction. The solid-state imaging device 1A according to the first embodiment therefore allows an improvement in photoelectric conversion efficiency.

Furthermore, in the solid-state imaging device 1A according to the first embodiment, the source region of the switching transistor FDG (the base part 52a of the first active region 56a), the gate electrode 59b of the amplification transistors AMP, and the charge holding region FD are aligned with each other in plan view. Then, the contact electrode 62 extends through the gate electrode 59b of the amplification transistor AMP and the source region of the switching transistor (the base part 52a of the first active region 56a). With such a configuration, the charge holding region FD, the source region of the switching transistor FDG (the base part 52a of the first active region 56a), and the gate electrode 59b of the amplification transistors AMP can be electrically connected at the shortest distance.

Furthermore, since the charge holding region FD, the source region of the switching transistor FDG (the base part 52a of the first active region 56a), and the gate electrode 59b of the amplification transistors AMP can be electrically connected at the shortest distance, it is possible to increase a read speed at which the readout circuit 15 including the switching transistor FDG and the amplification transistors AMP reads the signal charge held in the charge holding region FD.

Furthermore, in the solid-state imaging device 1A according to the first embodiment, the switching transistor FDG has a configuration in which the base part 52a of the first active region 56a and the first semiconductor part 55a provided in the protruding part 54a protruding from the base part 52a function as the source region. On the other hand, in the amplification transistors AMP, the gate electrode 59b is disposed outside the protruding part 54b protruding from the base part 52b of the second active region 56b with the gate insulating film 58 interposed therebetween, and the gate electrode 59b and the base part 52b are separated from each other in the vertical direction (Z direction). Then, the base part 52a of the first active region 56a and the base part 52b of the second active region 56b are arranged in the same plane. It is therefore possible to cause, by routing the gate electrode 59b of the amplification transistors AMP to above the source region (the base part 52a of the first active region 56a) of the switching transistor FDG, the source region of the switching transistor FDG and the gate electrode 59b of the amplification transistors AMP to align with each other with ease.

Furthermore, in the method for manufacturing the solid-state imaging device 1A according to the first embodiment, the gate electrode 59b of the amplification transistors AMP, the base part 52a of the first active region 56a functioning as the source region of the switching transistor FDG, and the charge holding region FD are electrically connected by the contact electrode 62 extending in the vertical direction (Z direction) through the semiconductor substrate 21 and the semiconductor layer 57, so that it is possible to manufacture the solid-state imaging device 1A having a three-dimensional structure.

### Second Embodiment

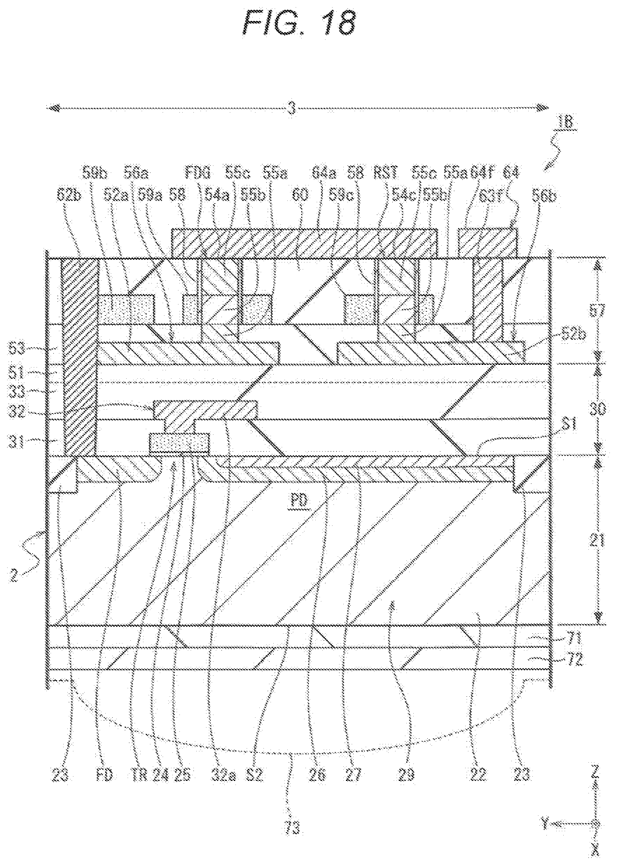

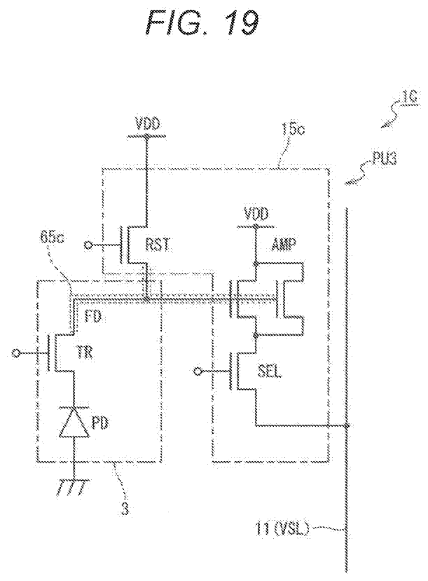

As illustrated in FIGS. 17 and 18, a solid-state imaging device 1B according to a second embodiment of the present technology is basically similar in configuration to the solid-state imaging device 1A according to the first embodiment described above, but is different in the following configuration.

That is, as illustrated in FIGS. 17 and 18, the solid-state imaging device 1B according to the second embodiment of the present technology includes a contact electrode 62b instead of the contact electrode 62 illustrated in FIGS. 4 and 5A of the first embodiment described above. Then, the contact electrode 62b has a different connection form. The other configuration is almost similar to the configuration of the first embodiment described above.

As illustrated in FIGS. 17 and 18, the contact electrode 62b according to the second embodiment is directly connected to the base part 52a of the first active region 56a functioning as the source region that is any one of the pair of main electrode regions of the switching transistor (first field effect transistor) FDG. Furthermore, the contact electrode 62b is directly connected to the gate electrode 59b of the amplification transistors (second field effect transistors) AMP and the charge holding region FD of the semiconductor substrate 21. Then, the contact electrode 62b is electrically continuous with the base part 52a, the gate electrode 59b, and the charge holding region FD. Referring to FIG. 3, the contact electrode 62b forms the conductive path 65 electrically connecting the source region of the switching transistor FDG, the gate electrode 59b of the amplification transistors AMP, and the charge holding region FD, as with the contact electrode 62 of the first embodiment described above.

In the second embodiment, the gate electrode 59b of the amplification transistors AMP, the base part 52a of the first active region 56a that is the source region of the switching transistor FDG, and the charge holding region FD are aligned with each other in plan view. Then, the contact electrode 62b linearly extends along the thickness direction (Z direction) of the semiconductor substrate 21 from the insulating film 60 side to the charge holding region FD across a side of the gate electrode 59b and a side of the base part 52a of the first active region 56a, and is directly connected to the gate electrode 59b, the base part 52a, and the charge holding region FD.

The contact electrode 62b can be formed by forming a connecting hole that extends from the surface side of the insulating film 60 to the surface of the charge holding region FD, and then embedding a conductive material in the connecting hole, as with the contact electrode 62 of the first embodiment described above.

The solid-state imaging device 1B according to the second embodiment can also produce effects similar to the effects produced by the solid-state imaging device 1A according to the first embodiment described above.

### Third Embodiment

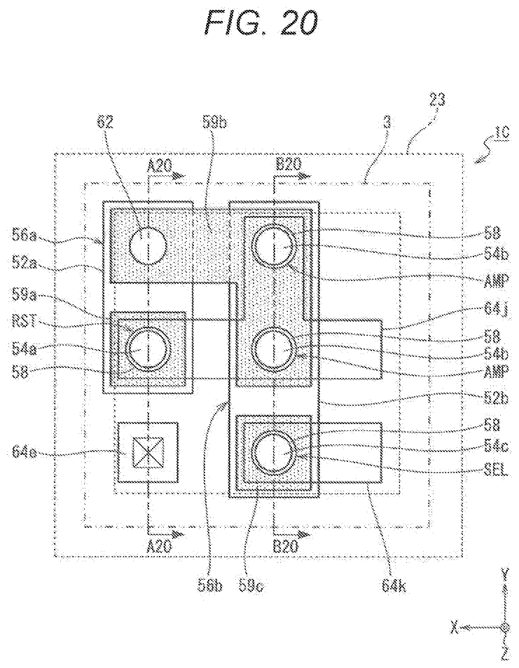

As illustrated in FIGS. 19 and 20, a solid-state imaging device 1C according to a third embodiment of the present technology is basically similar in configuration to the solid-state imaging device 1A according to the first embodiment described above, but is different in the following configuration.

That is, as illustrated in FIG. 19, the solid-state imaging device 1C according to the third embodiment of the present technology includes a pixel unit PU3 instead of the pixel unit PU illustrated in FIG. 3 of the first embodiment described above. The other configuration is almost similar to the configuration of the first embodiment described above.

As illustrated in FIG. 19, the pixel unit PU3 includes one pixel 3 and a readout circuit that reads out a signal charge held in the one pixel 3. Unlike the readout circuit 15, illustrated in FIG. 3, of the first embodiment described above, the readout circuit 15c of the third embodiment has a configuration in which the switching transistor FDG illustrated in FIG. 3 is omitted. That is, the readout circuit 15c of the third embodiment includes the reset transistor RST, the amplification transistors AMP, and the selection transistor SEL except for the switching transistor FDG illustrated in FIG. 3.

The reset transistor RST has the source region electrically connected to the gate electrode of each of the two amplification transistors AMP and the charge holding region FD, and the drain region electrically connected to the power line VDD. The connection form of the two amplification transistors AMP and the selection transistor SEL is similar to the connection form of the first embodiment described above.

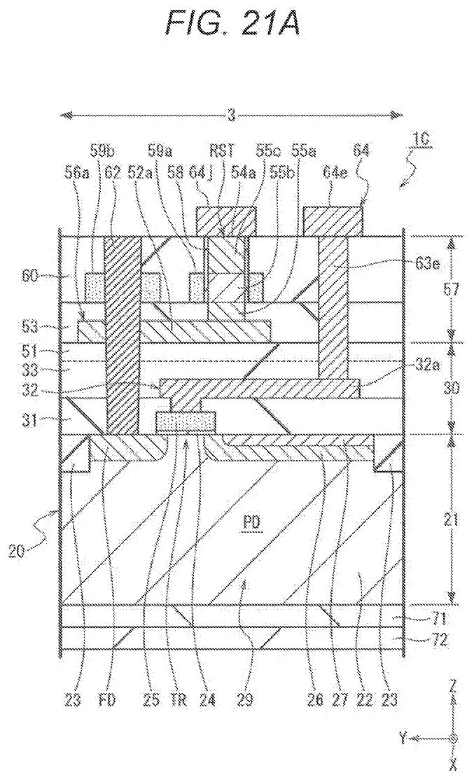

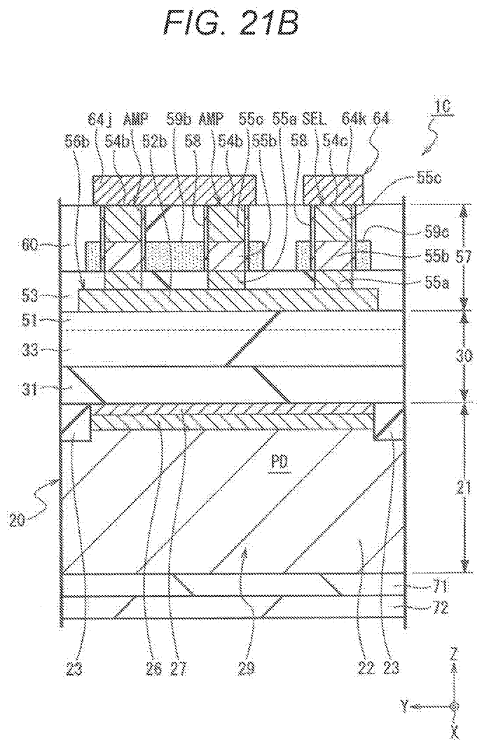

As illustrated in FIGS. 20, 21A, and 21B, the semiconductor layer 57 of the third embodiment includes the first active region 56a and the second active region 56b as in the first embodiment described above, but does not include the third active region 56d illustrated in FIG. 4 unlike the first embodiment described above. That is, each pixel 3 of the third embodiment includes the first active region 56a and the second active region 56b, and the third active region 56d illustrated in FIG. 4 is omitted.

As illustrated in FIGS. 20, 21A, and 21B, unlike the first embodiment described above, the first active region 56a is provided with, for example, the reset transistor RST as the first field effect transistor. Then, the second active region 56b is similar to the first embodiment described above in that, for example, the two amplification transistors AMP are provided as the second transistors, but in the third embodiment, the selection transistor SEL is provided instead of the reset transistor RST illustrated in FIG. 3.

(Reset Transistor) As illustrated in FIGS. 20 and 20A, unlike the first embodiment described above, the reset transistor RST includes the second semiconductor part 55b provided in the protruding part 54a of the first active region 56a and functioning as a channel formation region in which a channel is formed, and the gate electrode 59a disposed outside the second semiconductor part 55b with the gate insulating film 58 interposed therebetween. Furthermore, the reset transistor RST further includes a pair of main electrode regions functioning as a source region and a drain region. One of the pair of main electrode regions includes the base part 52a and the first semiconductor part 55a provided in the protruding part 54a, and functions as, for example, the source region. Then, the other of the pair of main electrode regions includes the third semiconductor part 55c provided in the protruding part 54a, and functions as, for example, the drain region. That is, the reset transistor RST has a vertical structure in which the pair of main electrode regions (the base part 52a and the first semiconductor part 55a, and the third semiconductor part 55c) are provided in the first active region 56a apart from each other in the protruding direction of the protruding part 54a with the channel formation region (the second semiconductor part 55b) interposed therebetween. The gate electrode 59a is provided to surround the second semiconductor part 55b of the protruding part 54a in plan view.

### (Amplification Transistor)

As illustrated in FIGS. 20 and 20B, each of the two amplification transistors AMP includes the second semiconductor part 55b provided in the protruding part 54b of the second active region 56b and functioning as a channel formation region in which a channel is formed, and the gate electrode 59b disposed outside the second semiconductor part 55b with the gate insulating film 58 interposed therebetween, as in the first embodiment described above. Furthermore, each of the two amplification transistors AMP further includes a pair of main electrode regions functioning as a source region and a drain region. One of the pair of main electrode regions includes the base part 52b and the first semiconductor part 55a provided in the protruding part 54b, and functions as, for example, the source region. Then, the other of the pair of main electrode regions includes the third semiconductor part 55c provided in the protruding part 54b, and functions as, for example, the drain region. That is, each of the two amplification transistors AMP has a vertical structure in which the pair of main electrode regions (the third semiconductor part 55c, and the base part 52a and the first semiconductor part 55a) are provided in the second active region 56b apart from each other in the protruding direction of the protruding part 54b with the channel formation region (the second semiconductor part 55b) interposed therebetween. The gate electrode 59b is provided to surround the second semiconductor part 55b of each of the two protruding parts 54b in plan view.

### (Selection Transistor)

As illustrated in FIGS. 20 and 20B, unlike the first embodiment described above, the selection transistor SEL includes the second semiconductor part 55b provided in the protruding part 54c of the second active region 56b and functioning as a channel formation region in which a channel is formed, and the gate electrode 59c disposed outside the second semiconductor part 55b with the gate insulating film 58 interposed therebetween. Furthermore, the selection transistor SEL further includes a pair of main electrode regions functioning as a source region and a drain region. One of the pair of main electrode regions includes the third semiconductor part 55c provided in the protruding part 54c, and functions as, for example, the source region. Then, the other of the pair of main electrode regions includes the base part 52b, and the first semiconductor part 55a provided in the protruding part 54c, and functions as, for example, the drain region. That is, the reset transistor RST has a vertical structure in which the pair of main electrode regions (the third semiconductor part 55c, and the base part 52b and the first semiconductor part 55a) are provided in the second active region 56b apart from each other in the protruding direction of the protruding part 54c with the channel formation region (the second semiconductor part 55b) interposed therebetween. The gate electrode 59c is provided to surround the second semiconductor part 55b of the protruding part 54c in plan view.

### (Sharing of Gate Electrode)

As illustrated in FIGS. 20, 21A, and 21B, the two amplification transistors AMP share the gate electrode 59b. The gate electrode 59b has a first portion that surrounds the second semiconductor part 55b of each of the two protruding parts 54b and extends along a longitudinal direction (Y direction) of the second active region 56b, and a second portion that extends from the first portion toward the first active region 56a and is aligned with the first active region 56a in plan view. That is, the gate electrode 59b is routed over the first active region 56a and the second active region 56b in the two-dimensional plane.

### (Sharing of Main Electrode Region)

As illustrated in FIGS. 20 and 21B, the two amplification transistors AMP and the selection transistor SEL share the base part 52b that functions as the source region of the amplification transistors AMP and the drain region of the selection transistor SEL.

### (Wiring Layer)

Next, as illustrated in FIGS. 20, 21A and 20B, the wiring layer 64 on the insulating film 60 is provided with wirings 64e, 64j, and 64k. Although not illustrated for convenience sake, these wirings 64e, 64j, and 64k are covered with an insulating film provided on the insulating film 60.

As illustrated in FIGS. 20 and 21A, the third semiconductor part 55c of the protruding part 54a is directly connected to the wiring 64j provided on the insulating film 60 to be electrically continuous with the wiring 64j. As illustrated in FIGS. 20 and 21B, the third semiconductor part 55c of each of the two protruding parts 54b is directly connected to one end side of the wiring 64b provided on the insulating film 60 to be electrically continuous with the wiring 64b. That is, the drain region of the reset transistor RST (the third semiconductor part 55c of the protruding part 54a) and the drain region of each of the two amplification transistors AMP (the third semiconductor portion 55c of the protruding part 54b) are electrically connected through the wiring 64j.

The wiring 64j is routed to be aligned with the protruding part 54a of the first active region 56a and each of the two protruding parts 54b of the second active region 56b in plan view. Then, although not illustrated in detail, the wiring 64j is electrically connected to the power line VDD illustrated in FIG. 19.

As illustrated in FIGS. 20 and 21B, the third semiconductor part 55c of the protruding part 54c is directly connected to the wiring 64k provided on the insulating film 60 to be electrically continuous with the wiring 64k. Then, although not illustrated in detail, the wiring 64k is electrically connected to the vertical signal line 11 illustrated in FIG. 19. That is, the source region of the selection transistor SEL is electrically connected to the vertical signal line 11 through the wiring 64k.

### (Conductive Path)

As illustrated in FIGS. 20 and 21A, the solid-state imaging device 1C according to the third embodiment further includes the contact electrode 62 that extends in the vertical direction (Z direction) through the semiconductor substrate 21 as the first semiconductor layer and the semiconductor layer 57 as the second semiconductor layer, as in the first embodiment described above.

The contact electrode 62 is directly connected to the base part 52a of the first active region 56a that functions as the source region that is any one of the pair of main electrode regions of the reset transistor (first field effect transistor) RST. Furthermore, the contact electrode 62 is directly connected to the gate electrode 59b of the amplification transistors (second field effect transistors) AMP and the charge holding region FD of the semiconductor substrate 21. Then, the contact electrode 62 is electrically continuous with the base part 52a, the gate electrode 59b, and the charge holding region FD. As illustrated in FIG. 19, the contact electrode 62 forms a conductive path 65c that electrically connects the source region of the reset transistor RST, the gate electrode 59b of the amplification transistors AMP, and the charge holding region FD.

In the third embodiment, the gate electrode 59b of the amplification transistors AMP, the base part 52a of the first active region 56a that is the source region of the reset transistor RST, and the charge holding region FD are aligned with each other in plan view. Then, the contact electrode 62 extends linearly along the thickness direction (Z direction) of the semiconductor substrate 21 from the insulating film 60 side to the charge holding region FD through the gate electrode 59b and the base part 52a of the first active region 56a, and is directly connected to the gate electrode 59b, the base part 52a, and the charge holding region FD.

The solid-state imaging device 1C according to the third embodiment can also produce effects similar to the effects produced by the solid-state imaging device 1A according to the first embodiment described above.

### Fourth Embodiment

A solid-state imaging device 1D according to a fourth embodiment of the present technology is basically similar in configuration to the solid-state imaging device 1A according to the first embodiment described above, but is different in the following configuration.

That is, referring to FIG. 4, in the solid-state imaging device 1A according to the first embodiment described above, each pixel 3 has a similar planar arrangement pattern including the first to third active regions 56a, 56b, and 56d of the semiconductor layer 57 and the pixel transistors (FDG, RST, AMP, SEL) of the readout circuit 15.

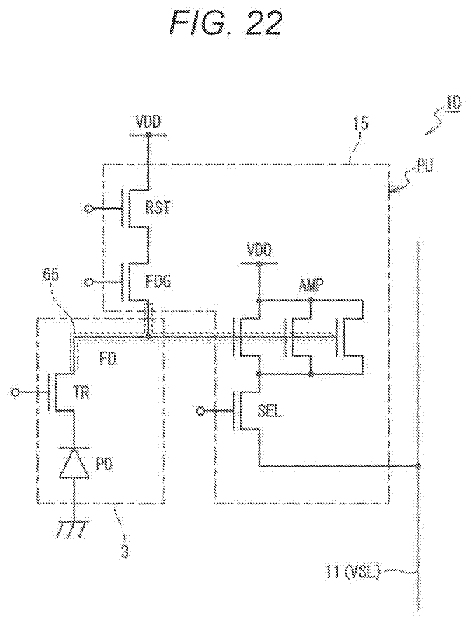

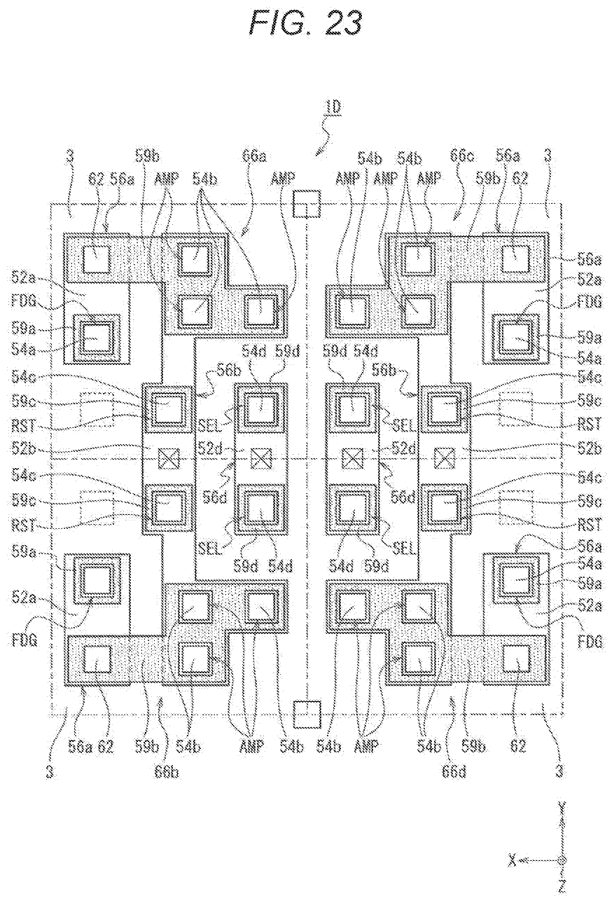

On the other hand, as illustrated in FIG. 23, in the solid-state imaging device 1D according to the fourth embodiment, planar arrangement patterns each including the first to third active regions 56a, 56b, and 56d of the semiconductor layer 57 and the pixel transistors (FDG, RST, AMP, SEL) of the readout circuit 15 of two pixels 3 adjacent to each other in each of the X direction and the Y direction are in a mirror-image relation. Then, in the fourth embodiment, for example, three amplification transistors AMP are connected in parallel as illustrated in FIG. 22.

Specifically, as illustrated in FIG. 23, four pixels 3 adjacent to each other in each of the X direction and the Y direction have a first planar arrangement pattern 66a, a second planar arrangement pattern 66b, a third planar arrangement pattern 66c, and a fourth planar arrangement pattern 66d as the planar arrangement pattern including the first to third active regions 56a, 56b, and 56d of the semiconductor layer 57 and the pixel transistors (FDG, RST, AMP, SEL) of the readout circuit 15. The first planar arrangement pattern 66a and the second planar arrangement pattern 66b, and the first planar arrangement pattern 66a and the third planar arrangement pattern 66c have line symmetry with respect to a boundary between two pixels 3 adjacent to each other. Furthermore, the fourth planar arrangement pattern 66d and the second planar arrangement pattern 66b, and the fourth planar arrangement pattern 66d and the third planar arrangement pattern 66c have line symmetry with respect to a boundary between two pixels 3 adjacent to each other.

Then, in the first and second planar arrangement patterns 66a and 66b, their respective second active regions 56b are combined with each other, and their respective third active regions 56d are combined with each other. Furthermore, in the third and fourth planar arrangement patterns 66c and 66d, their respective second active regions 56b are combined with each other, and their respective third active regions 56d are combined with each other. That is, a first unit planar arrangement pattern having the first and second planar arrangement patterns 66a and 66b as one unit and a second unit planar arrangement pattern having the third and fourth planar arrangement patterns 66c and 66d as one unit have line symmetry with respect to the boundary between two pixels 3 adjacent to each other. Then, referring to FIG. 1, in the pixel region 2A, pixel unit cells each having four pixels 3 as one unit illustrated in FIG. 23 are repeatedly arranged in the X direction and the Y direction. Then, as illustrated in FIG. 23, in the first to fourth planar arrangement patterns 66a, 66b, 66c, and 66d, the three amplification transistors AMP shares the gate electrode 59b.

The solid-state imaging device 1D according to the fourth embodiment can also produce effects similar to the effects produced by the solid-state imaging device 1A according to the first embodiment described above.

Furthermore, the solid-state imaging device 1D according to the fourth embodiment allows the three amplification transistors AMP to be connected in parallel, and further allows a reduction in noise in terms of size.

### Fifth Embodiment

A solid-state imaging device 1E according to a fifth embodiment of the present technology is basically similar in configuration to the solid-state imaging device 1A according to the first embodiment described above, but is different in the following configuration.

That is, as illustrated in FIG. 3, in the solid-state imaging device 1A according to the first embodiment described above, one pixel 3 is connected to one readout circuit 15.

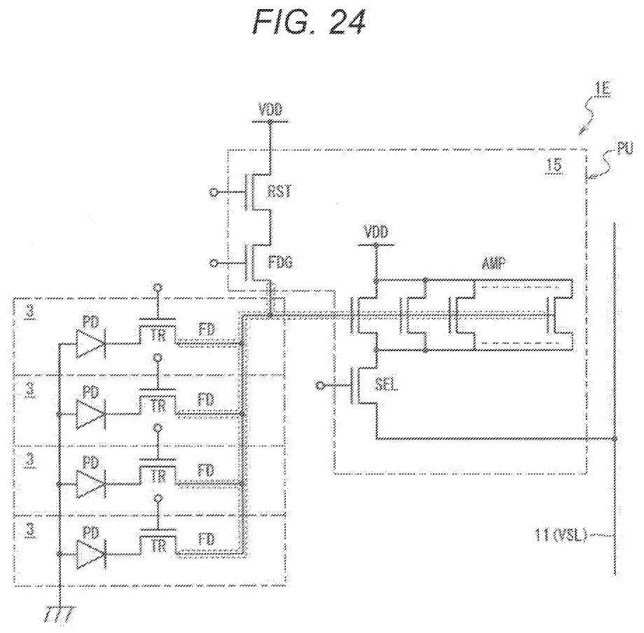

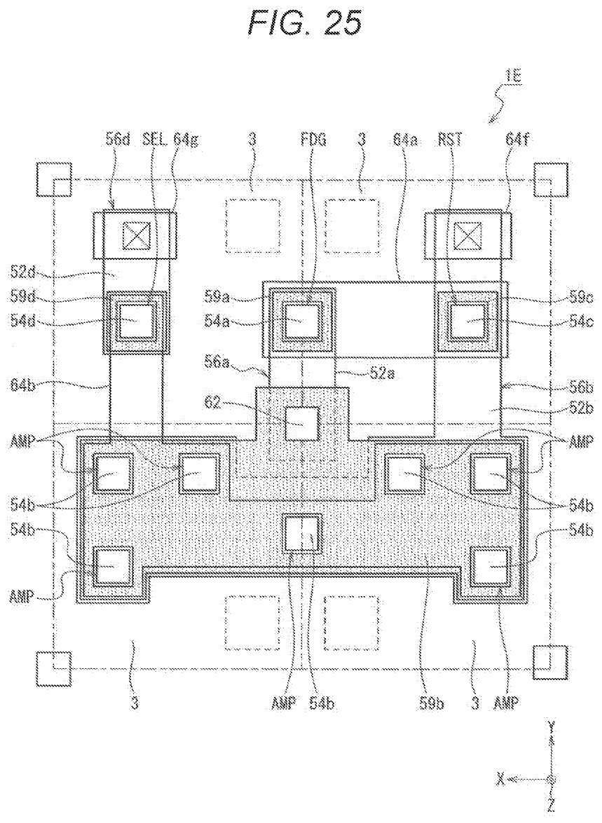

On the other hand, as illustrated in FIG. 24, in the solid-state imaging device 1E according to the fifth embodiment, four pixels 3 are connected to one readout circuit 15. That is, one first readout circuit 15 is shared by the four pixels 3. Then, as illustrated in FIGS. 24 and 25, in the fifth embodiment, seven amplification transistors AMP are connected in parallel, for example. Then, as illustrated in FIG. 25, the first active region 56a, the second active region 56b, and the third active region 56d are shared by the four pixels 3 arranged in a two-by-two matrix in the X direction and the Y direction. Then, the seven amplification transistors AMP shares one gate electrode 59b. Then, referring to FIG. 1, in the pixel region 2A, pixel unit cells each having four pixels 3 as one unit illustrated in FIG. 25 are repeatedly arranged in the X direction and the Y direction.

The solid-state imaging device 1E according to the fifth embodiment can also produce effects similar to the effects produced by the solid-state imaging device 1A according to the first embodiment described above.

Furthermore, the solid-state imaging device 1E according to the fifth embodiment allows the seven amplification transistors AMP to be connected in parallel, and further allows a reduction in noise in terms of size.

### Sixth Embodiment

### <<Example of Application to Electronic Device>>

The present technology (technology according to the present disclosure) may be applied to various electronic devices such as an imaging device such as a digital still camera or a digital video camera, a mobile phone having an imaging function, or other devices having an imaging function.

FIG. 26 is a diagram illustrating a schematic configuration of an electronic device (for example, a camera) according to a sixth embodiment of the present technology.

As illustrated in FIG. 26, an electronic device 100 includes a solid-state imaging device 101, an optical lens 102, a shutter device 103, a drive circuit 104, and a signal processing circuit 105. In the electronic device 100, the solid-state imaging devices 1A, 1B, 1C, 1D, and 1E according to the first to fifth embodiments of the present technology are used as the solid-state imaging device 101.

The optical lens 102 forms an image of image light (incident light 106) from a subject on an imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. A signal of the solid-state imaging device 101 is transferred by a drive signal (timing signal) supplied from the drive circuit 104. The signal processing circuit 105 performs various types of signal processing on a signal (pixel signal) output from the solid-state imaging device 101. A video signal subjected to the signal processing is stored in a storage medium such as a memory or output to a monitor.

With such a configuration, the electronic device 100 according to the second embodiment causes a light antireflection part in the solid-state imaging device 101 to inhibit light reflection off a light shielding film or an insulating film in contact with an air layer, so that it is possible to inhibit deviation and to improve image quality.

Note that the electronic device 100 to which the solid-state imaging device 1 can be applied is not limited to a camera, and the solid-state imaging device 1 can also be applied to other electronic devices. For example, the solid-state imaging device 1 may be applied to an imaging device such as a camera module for a mobile device such as a mobile phone or a tablet terminal.

### Other Embodiments

In the embodiments described above, the connection forms in which any one of the pair of main electrode regions of the first field effect transistor provided in the second semiconductor layer, the gate electrode of the second field effect transistor provided in the second semiconductor layer, and the charge holding region provided in the first semiconductor layer are electrically connected by the contact electrodes 62 and 62c extending in the vertical direction through the first and second semiconductor layers have been described. The present technology, however, is not limited to such connection forms of the contact electrodes 62 and 62c. For example, the present technology may also be applied to a connection form in which any two of any one of the pair of main electrode regions of the first field effect transistor provided in the second semiconductor layer, the gate electrode of the second field effect transistor provided in the second semiconductor layer, and the charge holding region provided in the first semiconductor layer are electrically connected by a contact electrode extending in the vertical direction.

Furthermore, in the embodiments described above, a case where one main electrode region of the first field effect transistor, the gate electrode of the second field effect transistor, and the charge holding region are aligned with each other in plan view has been described. The present technology, however, may also be applied to a case where the one main electrode region of the first field effect transistor and the gate electrode of the second field effect transistor are aligned with each other in plan view, and the charge holding region is not aligned with the one main electrode region of the first field effect transistor and the gate electrode of the second field effect transistor.

Note that the present technology may have the following configuration.

(1)

A solid-state imaging device including:
a first semiconductor layer;
a second semiconductor layer provided on a side of the first semiconductor layer remote from a light incident surface;
a photoelectric conversion part provided in the first semiconductor layer;
a charge holding region provided in the first semiconductor layer and configured to accumulate a signal charge generated by photoelectric conversion performed by the photoelectric conversion part;
first and second field effect transistors each including a gate electrode and a pair of main electrode regions, each of the pairs of main electrode regions being provided in the second semiconductor layer; and
a contact electrode extending through the first and second semiconductor layers and directly connected to any one of the pair of main electrode regions of the first field effect transistor, the gate electrode of the second field effect transistor, and the charge holding region.
   (2)

In the solid-state imaging device according to (1), the one main electrode region of the first field effect transistor and the gate electrode of the second field effect transistor are aligned with each other in plan view.

(3)

In the solid-state imaging device according to (1), the one main electrode region of the first field effect transistor, the gate electrode of the second field effect transistor, and the charge holding region are aligned with each other in plan view.

(4)

In the solid-state imaging device according to any one of (1) to (3), the contact electrode passes through the gate electrode of the second field effect transistor and the one main electrode region of the first field effect transistor.

(5)

In the solid-state imaging device according to any one of (1) to (3), the contact electrode extends across a side of the gate electrode of the second field effect transistor and a side of the one main electrode region of the first field effect transistor.

(6)

In the solid-state imaging device according to any one of (1) to (5), the second semiconductor layer includes a first active region and a second active region,
each of the first and second active regions includes a base part having an island shape and a protruding part protruding upward from the base part,
the first field effect transistor further includes a channel formation region provided in the protruding part of the first active region, the pair of main electrode regions of the first field effect transistor being provided in the first active region apart from each other in a protruding direction of the protruding part with the channel formation region interposed between the pair of main electrode regions, and the gate electrode of the first field effect transistor being disposed outside the channel formation region with a gate insulating film interposed between the gate electrode and the channel formation region, and
the second field effect transistor further includes a channel formation region provided in the protruding part of the second active region, the pair of main electrode regions of the second field effect transistor being provided in the second active region apart from each other in the protruding direction of the protruding part with the channel formation region interposed between the pair of main electrode regions, and the gate electrode of the second field effect transistor being disposed outside the channel formation region with a gate insulating film interposed between the gate electrode and the channel formation region and provided over the first and second active regions.
   (7)

The solid-state imaging device according to any one of (1) to (6), further including a transfer transistor provided in the first semiconductor layer and configured to transfer, to the charge holding region, the signal charge generated by photoelectric conversion performed by the photoelectric conversion part.

(8)

The solid-state imaging device according to any one of (1) to (7), further including a readout circuit including the first and second field effect transistors and configured to read out the signal charge held in the charge holding region.

(9)

In the solid-state imaging device according to (8), the first field effect transistor is a switching transistor or a reset transistor, and
the second field effect transistor is an amplification transistor.
   (10)

In the solid-state imaging device according to any one of (1) to (9), a wiring of a wiring layer located above the second semiconductor layer is not connected to the contact electrode.

(11)

An electronic device including:
a solid-state imaging device;
an optical lens configured to form an image of image light from a subject on an imaging surface of the solid-state imaging device; and
a signal processing circuit configured to perform signal processing on a signal output from the solid-state imaging device, in which
the solid-state imaging device includes:
a first semiconductor layer;
a second semiconductor layer provided on a side of the first semiconductor layer remote from a light incident surface;
a photoelectric conversion part provided in the first semiconductor layer;
a charge holding region provided in the first semiconductor layer and configured to accumulate a signal charge generated by photoelectric conversion performed by the photoelectric conversion part;
first and second field effect transistors each including a gate electrode and a pair of main electrode regions, each of the pairs of main electrode regions being provided in the second semiconductor layer; and
a contact electrode extending through the first and second semiconductor layers and directly connected to any one of the pair of main electrode regions of the first field effect transistor, the gate electrode of the second field effect transistor, and the charge holding region.

The scope of the present technology is not limited to the illustrated and described exemplary embodiments, and includes all embodiments that provide effects equivalent to the effects intended to be provided by the present technology. Moreover, the scope of the present technology is not limited to the combinations of the features of the invention defined by the claims, and may be defined by any desired combination of specific features among all the recited features.

### REFERENCE SIGNS LIST

1A, 1B, 1C, 1D, 1E Solid-state imaging device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
12 Horizontal signal line
13 Logic circuit
14 Bonding pad
15 Readout circuit
20 Semiconductor base
21 Semiconductor substrate (first semiconductor layer)
22 p-type well region
23 Isolation region
24 Gate insulating film
25 Gate electrode
26 n-type semiconductor region
27 p-type semiconductor region
29 Photoelectric conversion part
30 Insulating layer
31 Insulating film
32 Wiring
33 Insulating film
50 Semiconductor base
51 Insulating film
52 Semiconductor substrate
52a, 52b, 52d Base part
53 Insulating film
53a, 53b, 53c, 53d Opening part
54a, 54b, 54c, 54d Protruding part
55a First semiconductor part
55b Second semiconductor part
55c Third semiconductor part
56a First active region
56b Second active region
56d Third active region
57 Semiconductor layer (second semiconductor layer)
58 Gate insulating film
59a, 59b, 59c, 59d Gate electrode
60 Insulating film
61 Connecting hole
62, 63a, 63b, 63c Contact electrode
64 Wiring layer
64a, 64b, 64e, 64f, 64g Wiring
65c Conductive path
66a First planar arrangement pattern
66b Second planar arrangement pattern
66c Third planar arrangement pattern
66d Fourth planar arrangement pattern
71 Planarizing film
72 Color filter
73 Microlens
80 Semiconductor wafer
81 Scribe line
82 Chip formation region

What is claimed is:

1. A solid-state imaging device comprising:
a first semiconductor layer;
a second semiconductor layer provided on a side of the first semiconductor layer remote from a light incident surface;
a photoelectric conversion part provided in the first semiconductor layer;
a charge holding region provided in the first semiconductor layer and configured to accumulate a signal charge generated by photoelectric conversion performed by the photoelectric conversion part;
first and second field effect transistors each including a gate electrode and a pair of main electrode regions, each of the pairs of main electrode regions being provided in the second semiconductor layer; and
a contact electrode extending through the first and second semiconductor layers and directly connected to any one of the pair of main electrode regions of the first field effect transistor, the gate electrode of the second field effect transistor, and the charge holding region.

2. The solid-state imaging device according to claim 1, wherein
the one main electrode region of the first field effect transistor and the gate electrode of the second field effect transistor are aligned with each other in plan view.

3. The solid-state imaging device according to claim 1, wherein
the one main electrode region of the first field effect transistor, the gate electrode of the second field effect transistor, and the charge holding region are aligned with each other in plan view.

4. The solid-state imaging device according to claim 1, wherein
the contact electrode passes through the gate electrode of the second field effect transistor and the one main electrode region of the first field effect transistor.

5. The solid-state imaging device according to claim 1, wherein
the contact electrode extends across a side of the gate electrode of the second field effect transistor and a side of the one main electrode region of the first field effect transistor.

6. The solid-state imaging device according to claim 1, wherein
the second semiconductor layer includes a first active region and a second active region,
each of the first and second active regions includes a base part having an island shape and a protruding part protruding upward from the base part,
the first field effect transistor further includes a channel formation region provided in the protruding part of the first active region, the pair of main electrode regions of the first field effect transistor being provided in the first active region apart from each other in a protruding direction of the protruding part with the channel formation region interposed between the pair of main electrode regions, and the gate electrode of the first field effect transistor being disposed outside the channel formation region with a gate insulating film interposed between the gate electrode and the channel formation region, and
the second field effect transistor further includes a channel formation region provided in the protruding part of the second active region, the pair of main electrode regions of the second field effect transistor being provided in the second active region apart from each other in the protruding direction of the protruding part with the channel formation region interposed between the pair of main electrode regions, and the gate electrode of the second field effect transistor being disposed outside the channel formation region with a gate insulating film interposed between the gate electrode and the channel formation region and provided over the first and second active regions.

7. The solid-state imaging device according to claim 1, further comprising a transfer transistor provided in the first semiconductor layer and configured to transfer, to the charge holding region, the signal charge generated by photoelectric conversion performed by the photoelectric conversion part.

8. The solid-state imaging device according to claim 1, further comprising
a readout circuit including the first and second field effect transistors and configured to read out the signal charge held in the charge holding region.

9. The solid-state imaging device according to claim 8, wherein
the first field effect transistor is a switching transistor or a reset transistor, and
the second field effect transistor is an amplification transistor.

10. The solid-state imaging device according to claim 1, wherein
a wiring of a wiring layer located above the second semiconductor layer is not connected to the contact electrode.

11. An electronic device, comprising:
a solid-state imaging device;
an optical lens configured to form an image of image light from a subject on an imaging surface of the solid-state imaging device; and
a signal processing circuit configured to perform signal processing on a signal output from the solid-state imaging device, wherein
the solid-state imaging device includes:
a first semiconductor layer;
a second semiconductor layer provided on a side of the first semiconductor layer remote from a light incident surface;
a photoelectric conversion part provided in the first semiconductor layer;
a charge holding region provided in the first semiconductor layer and configured to accumulate a signal charge generated by photoelectric conversion performed by the photoelectric conversion part;
first and second field effect transistors each including a gate electrode and a pair of main electrode regions, each of the pairs of main electrode regions being provided in the second semiconductor layer; and
a contact electrode extending through the first and second semiconductor layers and directly connected to any one of the pair of main electrode regions of the first field effect transistor, the gate electrode of the second field effect transistor, and the charge holding region.
